(19) United States
(12) Patent Application Publication
(10) Pub. No.: US 2026/0362779 A1
(43) Pub. Date: Nov. 12, 2026

(54) SEMICONDUCTOR DEVICE WITH MULTI-LAYERED ETCH STOP LAYER

(71) Applicant: TAIWAN SEMICONDUCTOR MANUFACTURING COMPANY, LTD., Hsinchu (TW)

(72) Inventors: Ping-Cheng SUNG, Hsinchu City (TW); Kuo-Ju CHEN, Taichung City (TW)

(73) Assignee: TAIWAN SEMICONDUCTOR MANUFACTURING COMPANY, LTD., Hsinchu (TW)

(21) Appl. No.: 19/203,784

(22) Filed: May 9, 2025

(51) Int. Cl. H10D 64/62; H10D 30/00; H10D 30/01; H10D 64/01

(52) U.S. Cl. CPC H10D 64/62; H10D 30/019; H10D 30/501; H10D 64/01

(57) ABSTRACT

A method includes following steps. A source/drain feature is formed over a substrate. A first interlayer dielectric (ILD) layer is formed over the source/drain feature. A source/drain contact is formed in the first ILD layer to electrically couple to the source/drain feature. A first sub-layer of an etch stop layer is formed over the first ILD layer and the source/drain contact. An ion implantation process is performed on the first sub-layer of the etch stop layer. A second sub-layer of the etch stop layer is formed over the first sub-layer of the etch stop layer. A second ILD layer is formed over the second sub-layer of the etch stop layer. A source/drain via is formed extending through the second ILD layer, the second sub-layer of the etch stop layer, and the first sub-layer of the etch stop layer to the source/drain contact.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of gate-all-around field-effect transistors (GAA-FETs) in a three-dimensional view, in accordance with some embodiments.

FIGS. 2-5, 6A, 13A, 14A, 15A, 16A, 17A, 18A, and 19A illustrate cross-sectional views of intermediate stages in the manufacturing of GAA-FETs, corresponding to reference cross-section A-A′ illustrated in FIG. 1 that extends through a gate region along a longitudinal axis of the gate region, in accordance with some embodiments.

FIGS. 6B, 7B, 8B, 9B, 10B, 11B, 11C, 12B, 12D, 13B, 14B, 15B, 16B, 17B, 18B, 19B, 20B, 21B, 22B, 23B, 24B, 25B, 26B, 27B, and 28B illustrate cross-sectional views of intermediate stages in the manufacturing of GAA-FETs, corresponding to reference cross-section B-B′ illustrated in FIG. 1 that extends through a fin along a longitudinal axis of the fin, in accordance with some embodiments.

FIGS. 7A, 8A, 9A, 10A, 11A, 12A, 12C, 13C, 20A, 21A, 22A, 23A, 24A, 25A, 26A, 27A, 28A, and 28C illustrate cross-sectional views of intermediate stages in the manufacturing of GAA-FETs, corresponding to reference cross-section C-C′ illustrated in FIG. 1 that extends through source/drain regions along the longitudinal direction of the gate region, in accordance with some embodiments.

FIGS. 17C and 19C illustrate zoomed-in top views of intermediate stages in the manufacturing of GAA-FETs, in accordance with some embodiments.

FIGS. 29A-29C are cross-sectional views of GAA-FETs, in accordance with some embodiments of the present disclosure.

FIG. 30 illustrates an example of a FinFET in a three-dimensional view, in accordance with some embodiments.

FIGS. 31A, 32A, and 33A illustrate cross-sectional views of intermediate stages in the manufacturing of the FinFET, corresponding to reference cross-section A-A′ illustrated in FIG. 30.

FIGS. 31B, 32B, 33B, and 34-40 illustrate cross-sectional views of intermediate stages in the manufacturing of the FinFET, corresponding to reference cross-section B-B′ illustrated in FIG. 30.

FIGS. 31C and 31D illustrate cross-sectional views of intermediate stages in the manufacturing of the FinFET, corresponding to reference cross-section C-C′ illustrated in FIG. 30.

FIG. 41 is a cross-sectional view of FinFET, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 230 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The present disclosure is generally related to integrated circuit (IC) structures and methods of forming the same, and more particularly to fabricating gate-all-around (GAA) transistors or fin-type field-effect transistors (FinFETs). It is also noted that the present disclosure presents embodiments in the form of multi-gate transistors. Multi-gate transistors include those transistors whose gate structures are formed on at least two-sides of a channel region. These multi-gate devices may include a p-type metal-oxide-semiconductor device or an n-type metal-oxide-semiconductor device. Specific examples may be presented and referred to herein as FinFET, on account of their fin-like structure. Also presented herein are embodiments of a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), and/or other suitable channel configuration. Presented herein are embodiments of devices that may have one or more channel regions (e.g., nanosheets) associated with a single, contiguous gate structure. However, one of ordinary skill would recognize that the teaching can apply to a single channel (e.g., single nanosheet) or any number of channels. One of ordinary skill may recognize other examples of semiconductor devices that may benefit from aspects of the present disclosure.

Some embodiments discussed herein are discussed in the context of GAA-FETs formed using a gate-last process. In other embodiments, a gate-first process may be used. Also, some embodiments contemplate aspects used in planar devices, such as planar FETs, or in fin field-effect transistors (FinFETs).

In some embodiments, an air gap is formed in the interlayer dielectric (ILD) layer around the source/drain contact, so as to reduce the parasitic capacitance around the source/drain contact. In such cases, a seal implantation process is performed to seal an upper portion of the air gap. This seal implantation process is performed after the formation of the air gap in the ILD layer and the deposition of a middle contact etch stop layer (also called MCESL) over the ILD layer. The step serves to induce swelling in the material of the ILD, thereby sealing the air gap. However, this implant process may negatively impact the overlay shift window between the gate contact (VG) and the source/drain contacts, as well as increase channel resistance. The degradation of the overlay shift window primarily stems from degraded electrical insulation properties of the MCESL due to the introduction of seal implantation ions. Specifically, the seal implantation can elevate the leakage current density within the MCESL material, necessitating a greater separation between the gate contact and the source/drain contacts to prevent unwanted leakage currents. Additionally, the increase in channel resistance is chiefly caused by the penetration of seal implantation ions into the channel regions.

To address these challenges, the present disclosure provides a two-step MCESL formation method in various embodiments. This method includes initially depositing a first sub-layer of MCESL over the ILD, performing the seal implantation process, and subsequently depositing a second sub-layer of MCESL over the first sub-layer. This technique allows for reduced implant energy to achieve effective sealing without compromising the final thickness of the MCESL, thereby preserving its role as an etch stop layer.

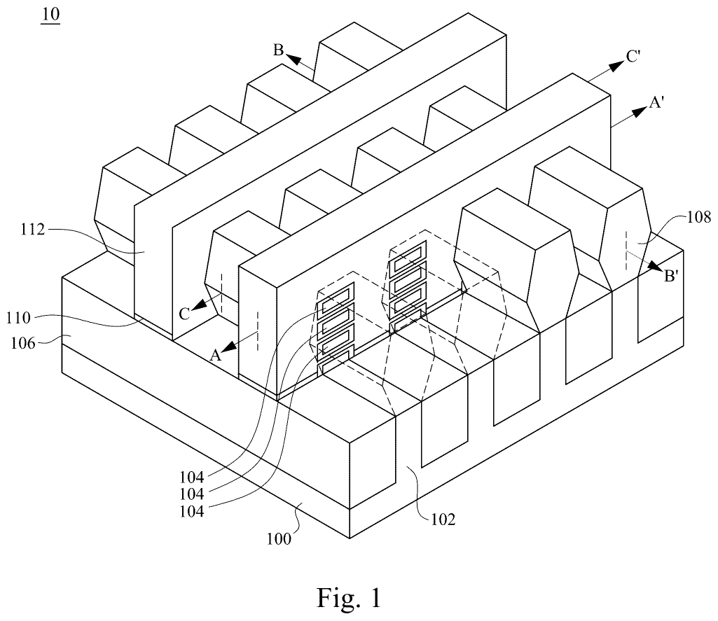

FIG. 1 illustrates an example of GAA-FETs (e.g., nanowire FETs, nanosheet FETs, or the like) in a three-dimensional view, in accordance with some embodiments. The GAA-FETs comprise nanostructures 104 (e.g., nanosheets, nanowires, nanorings, nanoslabs, or other structures having nano-scale size (e.g., a few nanometers)) over fins 102 on a substrate 100 (e.g., a semiconductor substrate), wherein the nanostructures 104 act as channel regions/active regions for the GAA-FETs. The nanostructure 104 may include p-type nanostructures, n-type nanostructures, or a combination thereof. Isolation regions 106 are disposed between adjacent fins 102, which may protrude above and from between neighboring isolation regions 106. Although the isolation regions 106 are described/illustrated as being separate from the substrate 100, as used herein, the term “substrate” may refer to the semiconductor substrate alone or a combination of the semiconductor substrate and the isolation regions. Additionally, although a bottom portion of the fins 102 are illustrated as being single, continuous materials with the substrate 100, the bottom portion of the fins 102 and/or the substrate 100 may comprise a single material or a plurality of materials. In this context, the fins 102 refer to the portion extending between the neighboring isolation regions 106.

Gate dielectrics 110 are over top surfaces of the fins 102 and along top surfaces, sidewalls, and bottom surfaces of the nanostructures 104. Gate electrodes 112 are over the gate dielectrics 110. Epitaxial source/drain regions 108 are disposed on the fins 102 on opposing sides of the gate dielectric layers 110 and the gate electrodes 112.

FIG. 1 further illustrates reference cross-sections that are used in later figures. Cross-section A-A′ is along a longitudinal axis of a gate electrode 112 and in a direction, for example, perpendicular to the direction of current flow between the epitaxial source/drain regions 108 of a GAA-FET. Cross-section B-B′ is perpendicular to cross-section A-A′ and is parallel to a longitudinal axis of a fin 102 of the GAA-FET and in a direction of, for example, a current flow between the epitaxial source/drain regions 108 of the GAA-FET. Cross-section C-C′ is parallel to cross-section A-A′ and extends through epitaxial source/drain regions of the GAA-FETs. Subsequent figures refer to these reference cross-sections for clarity.

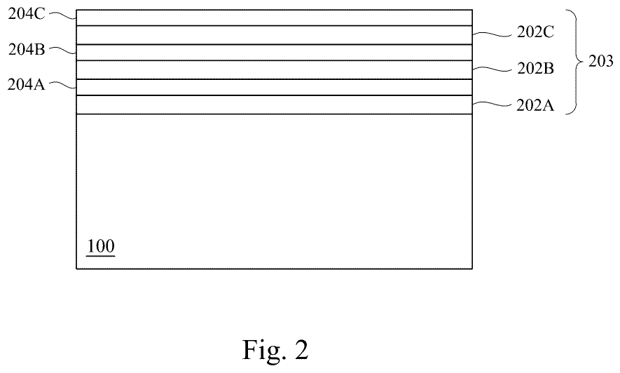

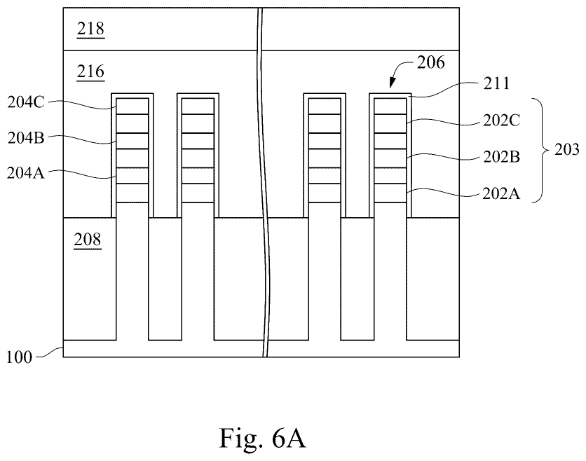

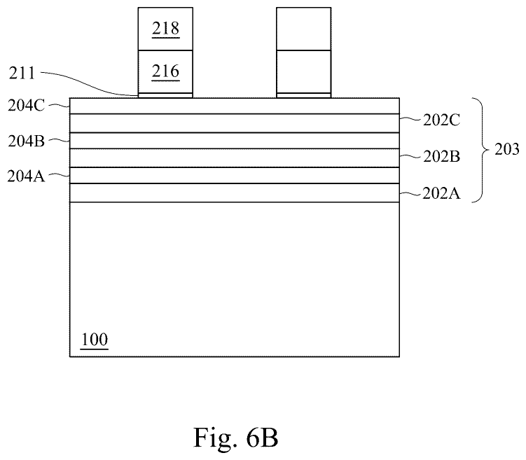

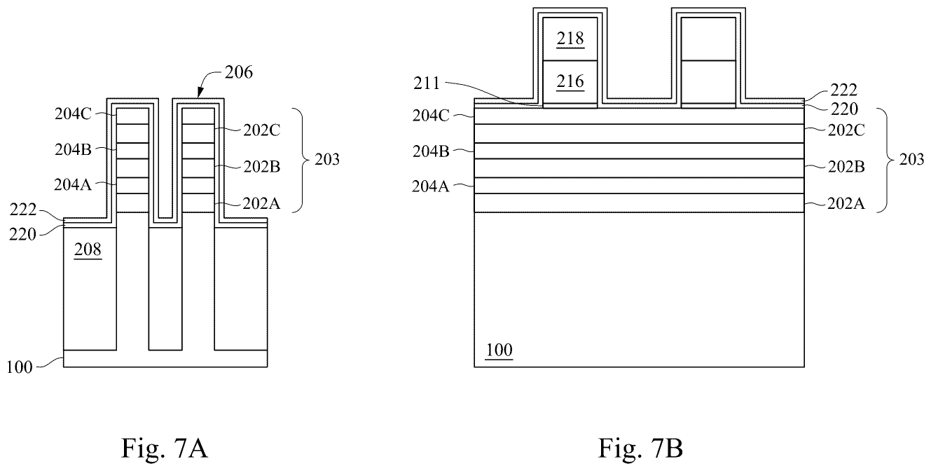

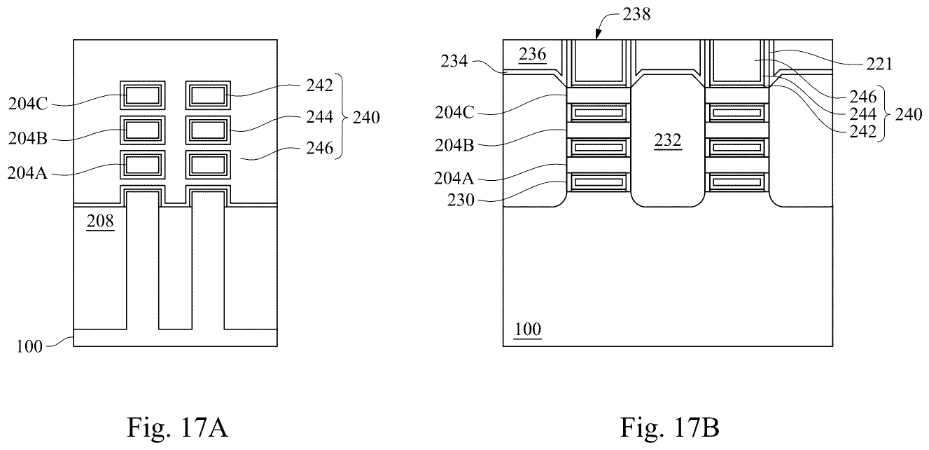

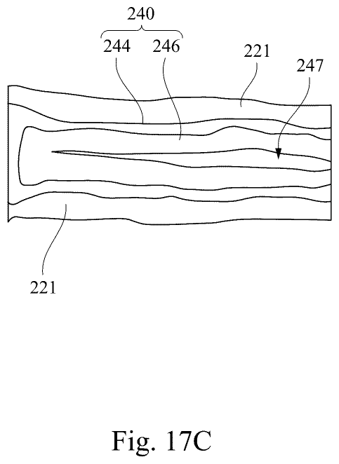

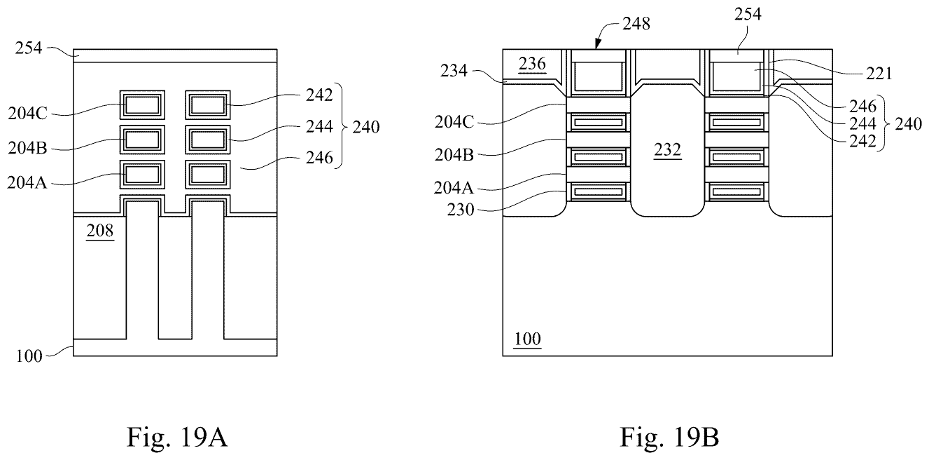

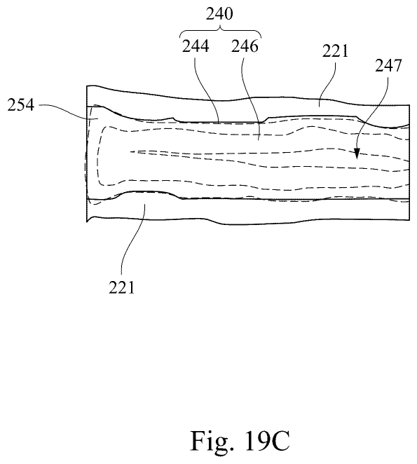

FIGS. 2 through 28C are cross-sectional views and top views of intermediate stages in the manufacturing of GAA-FETs, in accordance with some embodiments. FIGS. 2-5, 6A, 13A, 14A, 15A, 16A, 17A, 18A, and 19A illustrate reference cross-section A-A′ illustrated in FIG. 1 that extends through a gate region along a longitudinal axis of the gate region. FIGS. 6B, 7B, 8B, 9B, 10B, 11B, 11C, 12B, 12D, 13B, 14B, 15B, 16B, 17B, 18B, 19B, 20B, 21B, 22B, 23B, 24B, 25B, 26B, 27B, and 28B illustrate reference cross-section B-B′ illustrated in FIG. 1 that extends through a fin along a longitudinal axis of the fin. FIGS. 7A, 8A, 9A, 10A, 11A, 12A, 12C, 13C, 20A, 21A, 22A, 23A, 24A, 25A, 26A, 27A, 28A, and 28C illustrate reference cross-section C-C′ illustrated in FIG. 1 that extends through source/drain regions along the longitudinal direction of the gate region. FIGS. 17C and 19C illustrate zoomed-in top views of GAA-FETs in gate regions.

In FIG. 2, a substrate 100 is provided. The substrate 100 may be a semiconductor substrate, such as a bulk semiconductor, a semiconductor-on-insulator (SOI) substrate, or the like, which may be doped (e.g., with a p-type or an n-type dopant) or undoped. The substrate 100 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 100 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

Further in FIG. 2, a multi-layered stack 201 is formed over the substrate 100. The multi-layered stack 201 includes alternating layers of first semiconductor layers 202A-C (collectively referred to as first semiconductor layers 202) and second semiconductor layers 204A-C (collectively referred to as second semiconductor layers 204). For purposes of illustration and as discussed in greater detail below, the first semiconductor layers 202 will be removed and the second semiconductor layers 204 will be patterned to form channel regions of GAA-FETs.

The multi-layered stack 201 is illustrated as including three layers of each of the first semiconductor layers 202 and the second semiconductor layers 204 for illustrative purposes. In some embodiments, the multi-layered stack 201 may include any number of the first semiconductor layers 202 and the second semiconductor layers 204. Each of the layers of the multi-layered stack 201 may be epitaxially grown using a process such as chemical vapor deposition (CVD), atomic layer deposition (ALD), vapor phase epitaxy (VPE), molecular beam epitaxy (MBE), or the like. In various embodiments, the second semiconductor layers 204 may be formed of a semiconductor material suitable for serving as channel regions of GAA-FETs, such as silicon, silicon carbon, silicon germanium, or the like.

The first semiconductor materials and the second semiconductor materials may be materials having a high-etch selectivity to one another. As such, the first semiconductor layers 202 of the first semiconductor material may be removed without significantly removing the second semiconductor layers 204 of the second semiconductor material, thereby allowing the second semiconductor layers 204 to serve as channel regions of GAA-FETs.

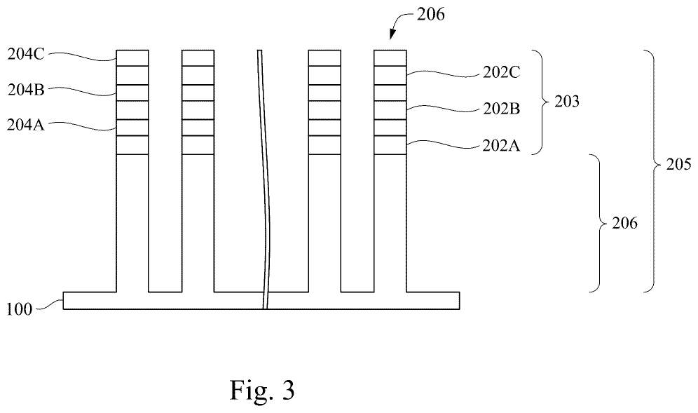

Referring now to FIG. 3, fin structures 206 are formed in the substrate 100 and nanostructures 203 are formed in the multi-layered stack 201, in accordance with some embodiments. In some embodiments, the nanostructures 203 and the fin structures 206 may be formed in the multi-layered stack 201 and the substrate 100, respectively, by etching trenches in the multi-layered stack 201 and the substrate 100. Each fin structure 206 and overlying nanostructures 203 can be collectively referred to as an active region 205. The etching may be any acceptable etch process, such as a reactive ion etch (RIE), neutral beam etch (NBE), the like, or a combination thereof. The etching may be anisotropic. Forming the nanostructures 203 by etching the multi-layered stack 201 may further define first nanostructures 202A-C (collectively referred to as the first nanostructures 202) from the first semiconductor layers 202 and define second nanostructures 204A-C (collectively referred to as the second nanostructures 204) from the second semiconductor layers 204. The first nanostructures 202 and the second nanostructures 204 may further be collectively referred to as nanostructures 203.

The fin structures 206 and the nanostructures 203 may be patterned by any suitable method. For example, the fin structures 206 and the nanostructures 203 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures 206. While each of the fin structures 206 and the nanostructures 203 are illustrated as having a consistent width throughout, in other embodiments, the fin structures 206 and/or the nanostructures 203 may have tapered sidewalls such that a width of each of the fin structures 206 and/or the nanostructures 203 continuously increases in a direction towards the substrate 100. In such embodiments, each of the nanostructures 203 may have a different width and be trapezoidal in shape.

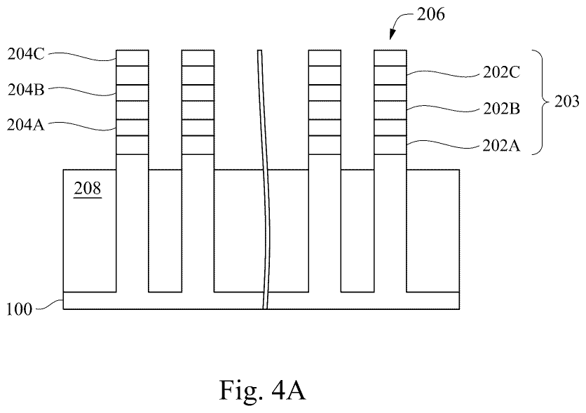

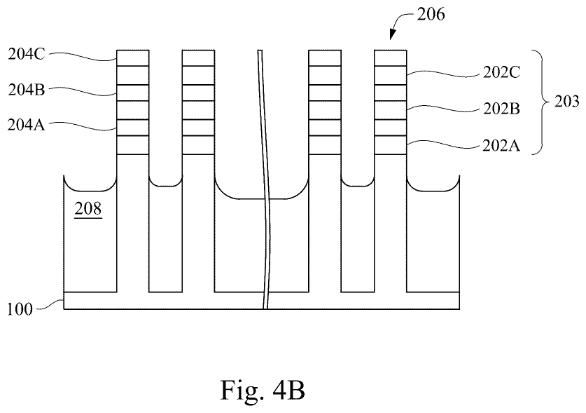

In FIG. 4A, shallow trench isolation (STI) regions 208 are formed adjacent the fin structures 206. The STI regions 208 may be formed by depositing an insulation material over the substrate 100, the fin structures 206, and nanostructures 203, and between adjacent fin structures 206. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 203. Although the insulation material is illustrated as a single layer, some embodiments may utilize multiple layers. For example, in some embodiments a liner (not separately illustrated) may first be formed along a surface of the substrate 100, the fin structures 206, and the nanostructures 203. Thereafter, a fill material, such as those discussed above may be formed over the liner.

A removal process is then applied to the insulation material to remove excess insulation material over the nanostructures 203. In some embodiments, a planarization process such as a chemical mechanical polish (CMP), an etch-back process, combinations thereof, or the like may be utilized. The planarization process exposes the nanostructures 203 such that top surfaces of the nanostructures 203 and the insulation material are level after the planarization process is complete.

The insulation material is then recessed to form the STI regions 208. The insulation material is recessed such that upper portions of fin structures 206 protrude from between neighboring STI regions 208. Further, the top surfaces of the STI regions 208 may have a flat surface as illustrated, a convex surface, a concave surface (such as dishing as illustrated in FIG. 4B), or a combination thereof. The top surfaces of the STI regions 208 may be formed flat, convex, and/or concave by an appropriate etch. The STI regions 208 may be recessed using an acceptable etching process, such as one that is selective to the material of the insulation material (e.g., etches the material of the insulation material at a faster rate than the material of the fin structures 206 and the nanostructures 203). For example, an oxide removal using, for example, dilute hydrofluoric (dHF) acid may be used. In some embodiments as illustrated in FIG. 4B, the top surfaces of the STI regions 208 are non-planar or concave. Moreover, recessed depths of the concave top surfaces of different STI regions 208 may be different, due to the width difference among different STI regions 208.

The process described above with respect to FIGS. 2 through 4B is just examples of how the fin structures 206 and the nanostructures 203 may be formed. In some embodiments, the fin structures 206 and/or the nanostructures 203 may be formed using a mask and an epitaxial growth process. For example, a dielectric layer can be formed over a top surface of the substrate 100, and trenches can be etched through the dielectric layer to expose the underlying substrate 100. Epitaxial structures can be epitaxially grown in the trenches, and the dielectric layer can be recessed such that the epitaxial structures protrude from the dielectric layer to form the fin structures 206 and/or the nanostructures 203. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Further, appropriate wells (not separately illustrated) may be formed in the fin structures 206 and/or the nanostructures 203. In some embodiments with different well types in different device regions (e.g., NFET region and PFET region), different implant steps may be achieved using a photoresist or other masks (not separately illustrated). For example, a photoresist may be formed over the fin structures 206 and the STI regions 208 in the NFET region and the PFET region. The photoresist is patterned to expose the PFET region. The photoresist can be formed by using a spin-on technique and can be patterned using acceptable photolithography techniques. Once the photoresist is patterned, a first impurity (e.g., n-type impurity such as phosphorus, arsenic, antimony, or the like) implant is performed in the PFET region, and the photoresist may act as a mask to substantially prevent the first impurities from being implanted into the NFET region. After the implant, the photoresist is removed, such as by an acceptable ashing process.

Following or prior to the implanting of the PFET region, a photoresist or other masks (not separately illustrated) is formed over the fin structures 206, the nanostructures 203, and the STI regions 208 in the NFET region and the PFET region. The photoresist is then patterned to expose the NFET region. The photoresist can be formed by using a spin-on technique and can be patterned using acceptable photolithography techniques. Once the photoresist is patterned, a second impurity (e.g., p-type impurity such as boron, boron fluoride, indium, or the like) implant may be performed in the NFET region, and the photoresist may act as a mask to substantially prevent p-type impurities from being implanted into the PFET region. After the implant, the photoresist may be removed, such as by an acceptable ashing process.

After one or more well implants of the NFET region and PFET region, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

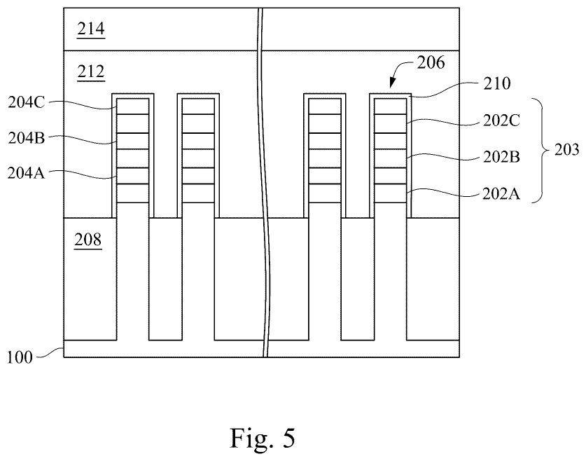

In FIG. 5, a dummy dielectric layer 210 is formed on the fin structures 206 and/or the nanostructures 203. The dummy dielectric layer 210 may be, for example, silicon oxide, silicon nitride, a combination thereof, or the like, and may be deposited or thermally grown according to acceptable techniques. A dummy gate layer 212 is formed over the dummy dielectric layer 210, and a mask layer 214 is formed over the dummy gate layer 212. The dummy gate layer 212 may be deposited over the dummy dielectric layer 210 and then planarized, such as by a CMP. The mask layer 214 may be deposited over the dummy gate layer 212. The dummy gate layer 212 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 212 may be deposited by physical vapor deposition (PVD), CVD, sputter deposition, or other techniques for depositing the selected material. The dummy gate layer 212 may be made of other materials that have a high etching selectivity from the etching of isolation regions. The mask layer 214 may include, for example, silicon nitride, silicon oxynitride, or the like. It is noted that the dummy dielectric layer 210 is shown covering only the fin structures 206 and the nanostructures 203 for illustrative purposes only. In some embodiments, the dummy dielectric layer 210 may be deposited such that the dummy dielectric layer 210 covers the STI regions 208, such that the dummy dielectric layer 210 extends between the dummy gate layer 212 and the STI regions 208.

In FIGS. 6A and 6B, the mask layer 214 (see FIG. 5) may be patterned using acceptable photolithography and etching techniques to form masks 218. The pattern of the masks 218 then may be transferred to the dummy gate layer 212 and to the dummy dielectric layer 210 to form dummy gates 216 and dummy gate dielectrics 211, respectively. The dummy gates 216 cover respective channel regions of the fin structures 206. The pattern of the masks 218 may be used to physically separate each of the dummy gates 216 from adjacent dummy gates 216. The dummy gates 216 may also have a lengthwise direction substantially perpendicular to the lengthwise direction of respective fin structures 206.

In FIGS. 7A and 7B, a first spacer layer 220 and a second spacer layer 222 are formed over the structures illustrated in FIGS. 6A and 6B, respectively. The first spacer layer 220 and the second spacer layer 222 will be subsequently patterned to act as spacers for forming self-aligned source/drain regions. In FIGS. 7A and 7B, the first spacer layer 220 is formed on top surfaces of the STI regions 208; top surfaces and sidewalls of the fin structures 206, the nanostructures 203, and the masks 218; and sidewalls of the dummy gates 216 and the dummy gate dielectric 211. The second spacer layer 222 is deposited over the first spacer layer 220. The first spacer layer 220 may be formed of silicon oxide, silicon nitride, silicon oxynitride, or the like, using techniques such as thermal oxidation or deposited by CVD, ALD, or the like. The second spacer layer 222 may be formed of a material having a different etch rate than the material of the first spacer layer 220, such as silicon oxide, silicon nitride, silicon oxynitride, or the like, and may be deposited by CVD, ALD, or the like.

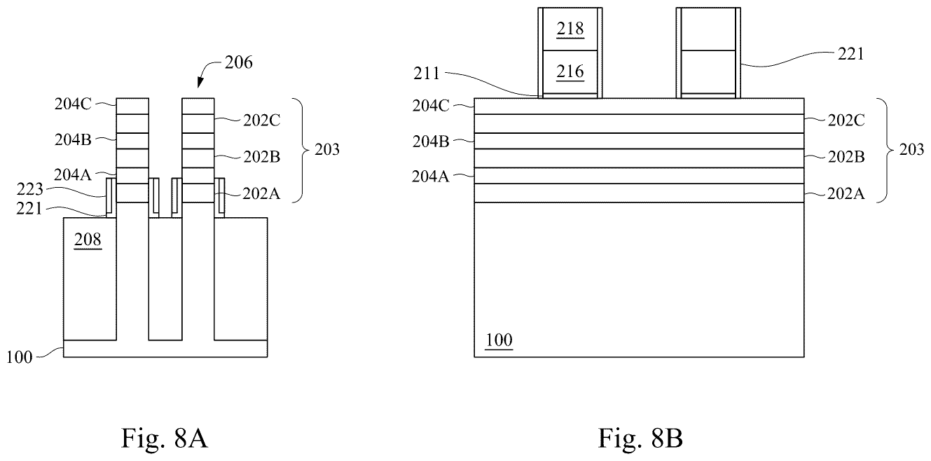

In FIGS. 8A and 8B, the first spacer layer 220 and the second spacer layer 222 are etched to form first spacers 221 and second spacers 223. As will be discussed in greater detail below, the first spacers 221 and the second spacers 223 act to self-align subsequently formed source and drain regions (collectively referred to as source/drain regions), as well as to protect sidewalls of the fin structures 206 and/or nanostructure 203 during subsequent processing. The first spacer layer 220 and the second spacer layer 222 may be etched using a suitable etching process, such as an isotropic etching process (e.g., a wet etching process), an anisotropic etching process (e.g., a dry etching process), or the like. In some embodiments, the material of the second spacer layer 222 has a different etch rate than the material of the first spacer layer 220, such that the first spacer layer 220 may act as an etch stop layer when patterning the second spacer layer 222 and such that the second spacer layer 222 may act as a mask when patterning the first spacer layer 220. For example, the second spacer layer 222 may be etched using an anisotropic etch process wherein the first spacer layer 220 acts as an etch stop layer, wherein remaining portions of the second spacer layer 222 form second spacers 223 as illustrated in FIG. 8A. Thereafter, the second spacers 223 acts as a mask while etching exposed portions of the first spacer layer 220, thereby forming first spacers 221 as illustrated in FIG. 8A.

As illustrated in FIG. 8A, the first spacers 221 and the second spacers 223 are disposed on sidewalls of the fin structures 206 and/or nanostructures 203. In some embodiments, the spacers 221 and 223 only partially remain on sidewalls of the fin structures 206. In some embodiments, no spacer remains on sidewalls of the fin structures 206. As illustrated in FIG. 8B, in some embodiments, the second spacer layer 222 may be removed from over the first spacer layer 220 adjacent the masks 218, the dummy gates 216, and the dummy gate dielectrics 211, and the first spacers 221 are disposed on sidewalls of the masks 218, the dummy gates 216, and the dummy dielectric layers 211. In other embodiments, a portion of the second spacer layer 222 may remain over the first spacer layer 220 adjacent the masks 218, the dummy gates 216, and the dummy gate dielectrics 211.

In some embodiments, the first spacers 221 on gate sidewalls (also called gate spacers) have a small thickness (e.g., in a range from about 1 nm to about 10 nm) so as to reduce gate-to-gate pitch without significant reduction in source/drain region size. In some embodiments, the first spacers 221 on gate sidewalls is formed of as low-dielectric constant (low-k) materials (e.g., porous silicon oxide) having a k-value, for example, less than about 3.5. The low-k material can aid in reducing parasitic capacitance between, for example, the subsequently formed metal gates and source/drain contacts.

The above disclosure generally describes a process of forming spacers. Other processes and sequences may be used. For example, fewer or additional spacers may be utilized, different sequence of steps may be utilized (e.g., the first spacers 221 may be patterned prior to depositing the second spacer layer 222), additional spacers may be formed and removed, and/or the like.

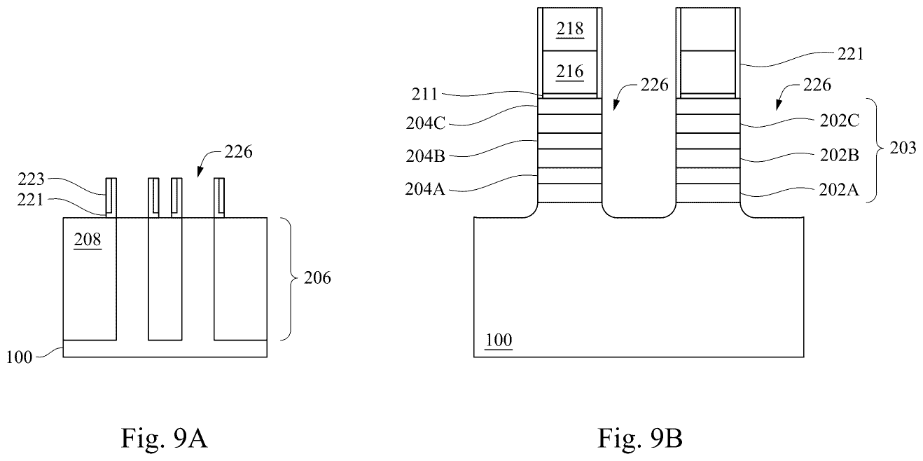

In FIGS. 9A and 9B, source/drain recesses 226 are formed in the fin structures 206, the nanostructures 203, and the substrate 100, in accordance with some embodiments. Epitaxial source/drain regions will be subsequently formed in the source/drain recesses 226. The source/drain recesses 226 may extend through the first nanostructures 202 and the second nanostructures 204, and into the substrate 100. As illustrated in FIG. 9A, bottom surfaces of the source/drain recesses 226 may be level with top surfaces of the STI regions 208, as an example. In some other embodiments, the fin structures 206 may be etched such that bottom surfaces of the source/drain recesses 226 are disposed below the top surfaces of the STI regions 208, or above the top surfaces of the STI regions 208. The source/drain recesses 226 may be formed by etching the fin structures 206, the nanostructures 203, and the substrate 100 using anisotropic etching processes, such as RIE, NBE, or the like. The first spacers 221, the second spacers 223, and the masks 218 mask portions of the fin structures 206, the nanostructures 203, and the substrate 100 during the etching processes used to form the source/drain recesses 226. A single etch process or multiple etch processes may be used to etch each layer of the nanostructures 203 and/or the fin structures 206. Timed etch processes may be used to stop the etching of the source/drain recesses 226 after the source/drain recesses 226 reach a target depth.

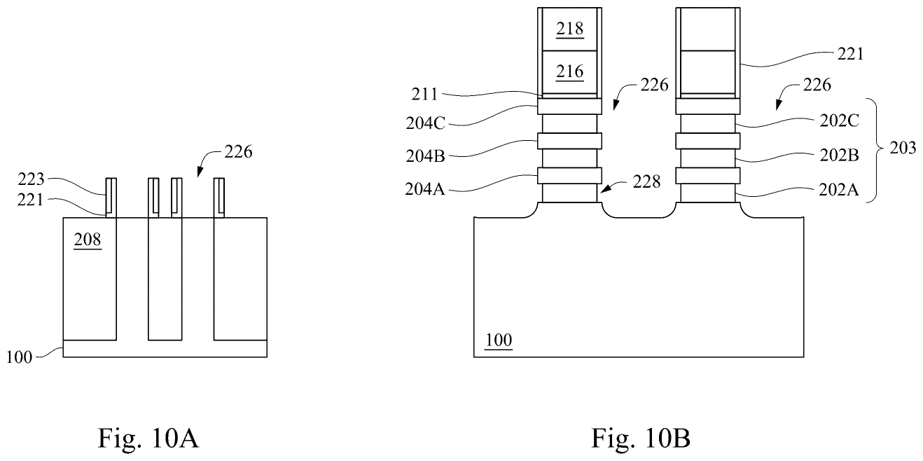

In FIGS. 10A and 10B, portions of sidewalls of the layers of the multi-layered nanostructure 203 formed of the first semiconductor materials (e.g., the first nanostructures 202) exposed by the source/drain recesses 226 are etched to form sidewall recesses 228 between corresponding second nanostructures 204. Although sidewalls of the first nanostructures 202 in recesses 228 are illustrated as being straight in FIG. 10B, the sidewalls may be concave or convex. The sidewalls may be etched using isotropic etching processes, such as wet etching or the like. In some embodiments in which the first nanostructures 202 include, e.g., SiGe, and the second nanostructures 204 include, e.g., Si or SiC, a dry etch process with tetramethylammonium hydroxide (TMAH), ammonium hydroxide (NH₄OH), or the like may be used to etch sidewalls of the first nanostructures 202.

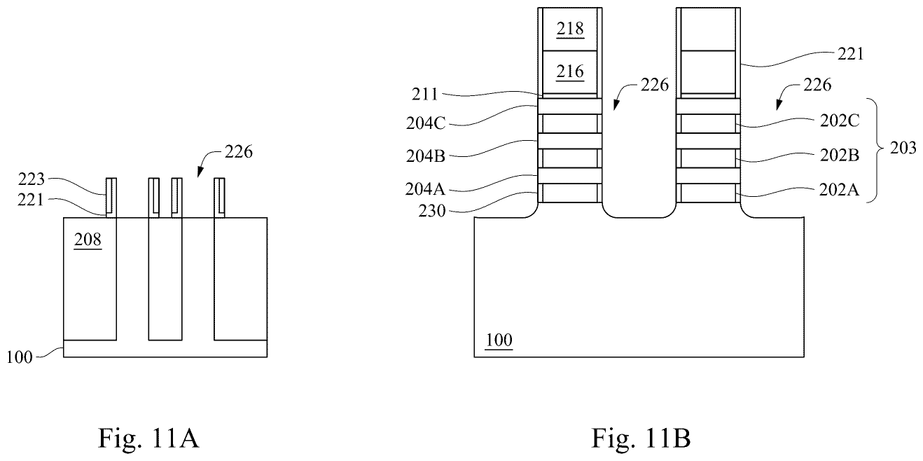

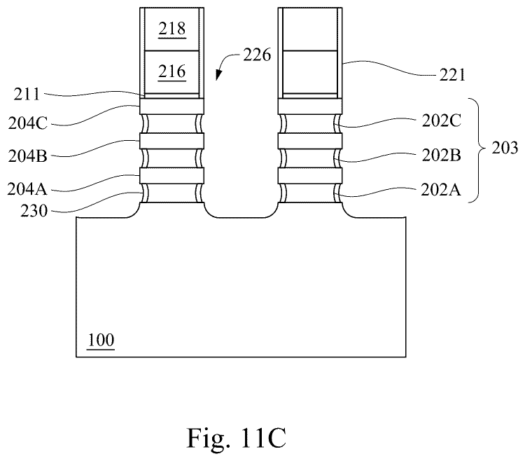

In FIGS. 11A-11C, inner spacers 230 are formed in the sidewall recess 228. The inner spacers 230 may be formed by depositing an inner spacer layer (not separately illustrated) over the structures illustrated in FIGS. 10A and 10B. The inner spacers 230 act as isolation features between subsequently formed source/drain regions and gate structure. As will be discussed in greater detail below, source/drain regions will be formed in the recesses 226, and the first nanostructures 202 will be replaced with corresponding gate structures. Source/drain region(s) may refer to a source or a drain, individually or collectively depending on the context.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 230. Although outer sidewalls of the inner spacers 230 are illustrated as being flush with sidewalls of the second nanostructures 204, the outer sidewalls of the inner spacers 230 may extend beyond or be recessed from sidewalls of the second nanostructures 204.

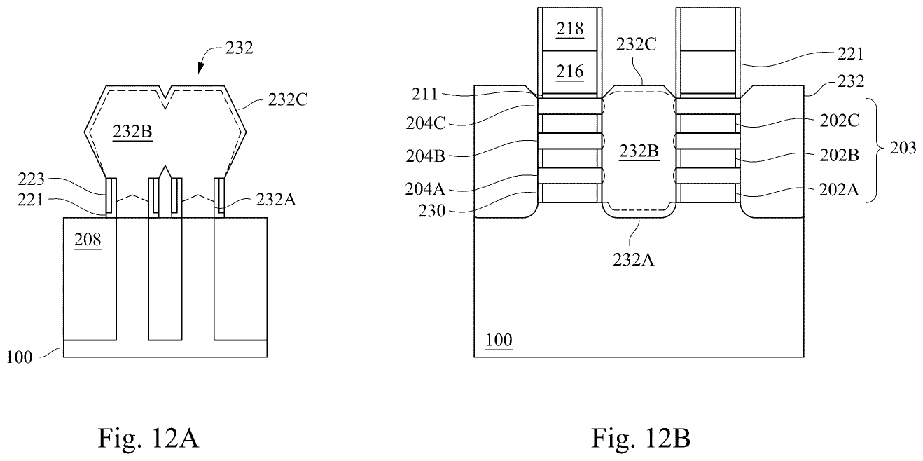

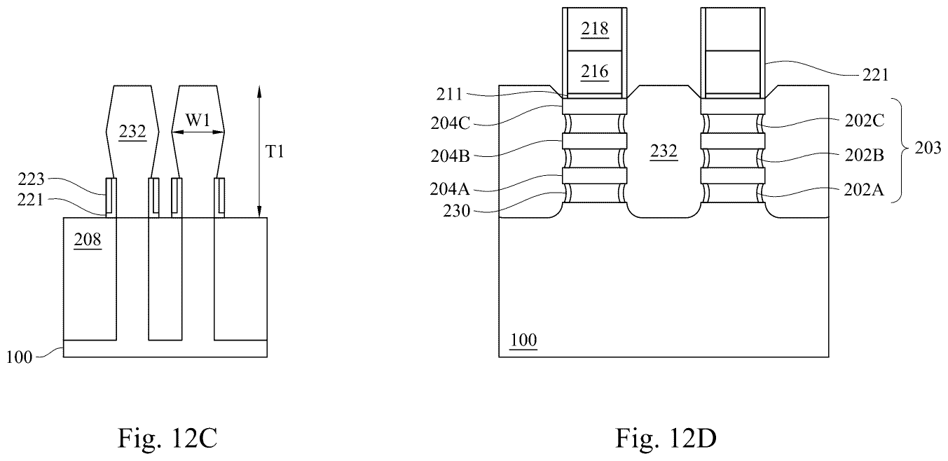

Moreover, although the outer sidewalls of the inner spacers 230 are illustrated as being straight in FIG. 11B, the outer sidewalls of the inner spacers 230 may be concave or convex. As an example, FIG. 11C illustrates an embodiment in which sidewalls of the first nanostructures 202 are concave, outer sidewalls of the inner spacers 230 are concave, and the inner spacers are recessed from sidewalls of the second nanostructures 204. The inner spacer layer may be etched by an anisotropic etching process, such as RIE, NBE, or the like. The inner spacers 230 may be used to prevent damage to subsequently formed source/drain regions (such as the epitaxial source/drain regions 232, discussed below with respect to FIGS. 12A-12D) by subsequent etching processes, such as etching processes used to form gate structures.

In FIGS. 12A-12D, epitaxial source/drain regions 232 are formed in the source/drain recesses 226. In some embodiments, the source/drain regions 232 may exert stress on the second nanostructures 204, thereby improving device performance. As illustrated in FIG. 12B, the epitaxial source/drain regions 232 are formed in the source/drain recesses 226 such that each dummy gate 216 is disposed between respective neighboring pairs of the epitaxial source/drain regions 232. In some embodiments, the first spacers 221 are used to separate the epitaxial source/drain regions 232 from the dummy gates 212, and the inner spacers 230 are used to separate the epitaxial source/drain regions 232 from the first nanostructures 202 by an appropriate lateral distance so that the epitaxial source/drain regions 232 do not short out with subsequently formed gates of the resulting GAA-FETs.

In some embodiments, the epitaxial source/drain regions 232 may include any acceptable material appropriate for n-type GAA-FETs. For example, if the second nanostructures 204 are silicon, the epitaxial source/drain regions 232 may include materials exerting a tensile strain on the second nanostructures 204, such as silicon carbide, phosphorous doped silicon carbide, silicon phosphide, or the like. In some embodiments, the epitaxial source/drain regions 232 may include any acceptable material appropriate for p-type GAA-FETs. For example, if the second nanostructures 204 are silicon, the epitaxial source/drain regions 232 may comprise materials exerting a compressive strain on the second nanostructures 204, such as silicon germanium, boron doped silicon germanium, germanium, germanium tin, or the like. The epitaxial source/drain regions 232 may have surfaces raised from respective upper surfaces of the nanostructures 203 and may have facets.

The epitaxial source/drain regions 232 may be implanted with dopants to form source/drain regions, followed by an anneal. The source/drain regions may have an impurity concentration of between about 1×10¹⁷ atoms/cm³ and about 1×10²² atoms/cm³. The n-type and/or p-type impurities for source/drain regions may be any of the impurities previously discussed. In some embodiments, the epitaxial source/drain regions 232 may be in situ doped during growth.

As a result of the epitaxy processes used to form the epitaxial source/drain regions 232, upper surfaces of the epitaxial source/drain regions 232 have facets which expand laterally outward beyond sidewalls of the nanostructures 203. In some embodiments, these facets cause adjacent epitaxial source/drain regions 232 to merge as illustrated by FIG. 12A. In some other embodiments, adjacent epitaxial source/drain regions 232 remain separated after the epitaxy process is completed as illustrated by FIG. 12C. In the embodiments illustrated in FIGS. 12A and 12C, the first spacers 221, 223 may be formed to a top surface of the STI regions 208 thereby blocking the lateral epitaxial growth. In some other embodiments, the spacer etch used to form the first spacers 221, 223 may be adjusted to remove the spacer material to allow the epitaxially grown region to extend to the surface of the STI region 208.

The epitaxial source/drain regions 232 may comprise one or more semiconductor material layers, with at least two layers containing same semiconductor material with difference concentrations. For example, the epitaxial source/drain regions 232 may comprise a first semiconductor material layer 232A, a second semiconductor material layer 232B, and a third semiconductor material layer 232C, which are distinguished in FIGS. 12A and 12B by using dash lines. Any number of semiconductor material layers may be used for the epitaxial source/drain regions 232. Each of the first semiconductor material layer 232A, the second semiconductor material layer 232B, and the third semiconductor material layer 232C may be formed of same or different semiconductor materials and may be doped to different dopant concentrations. In some embodiments, the first semiconductor material layer 232A may have a dopant concentration less than the second semiconductor material layer 232B and greater than the third semiconductor material layer 232C. In embodiments in which the epitaxial source/drain regions 232 comprise three semiconductor material layers, the first semiconductor material layer 232A may be deposited, the second semiconductor material layer 232B may be deposited over the first semiconductor material layer 232A, and the third semiconductor material layer 232C may be deposited over the second semiconductor material layer 232B. The epitaxial source/drain regions 232 are at least partially embedded in the substrate 100 and adjacent to channel regions (i.e., second nanostructures 204). As illustrated in FIG. 12C, each epitaxial source/drain region 232 has a thickness T1 measured in a vertical direction and a width W1 measured in a horizontal direction, and the thickness T1 is different from the width W1. In some embodiments, the width W1 of the epitaxial source/drain region 232 has the width W1 greater than a width of the fin structure 206, such that a portion of the epitaxial source/drain region 232 overhangs the STI region 208.

FIG. 12D illustrates an embodiment in which sidewalls of the first nanostructures 202 are concave, outer sidewalls of the inner spacers 230 are concave, and the inner spacers 230 are recessed from sidewalls of the second nanostructures 204. As illustrated in FIG. 12D, the epitaxial source/drain regions 232 may be formed in contact with the inner spacers 230 and may extend past sidewalls of the second nanostructures 204.

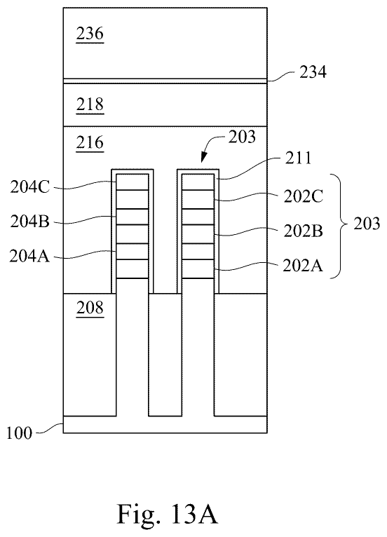

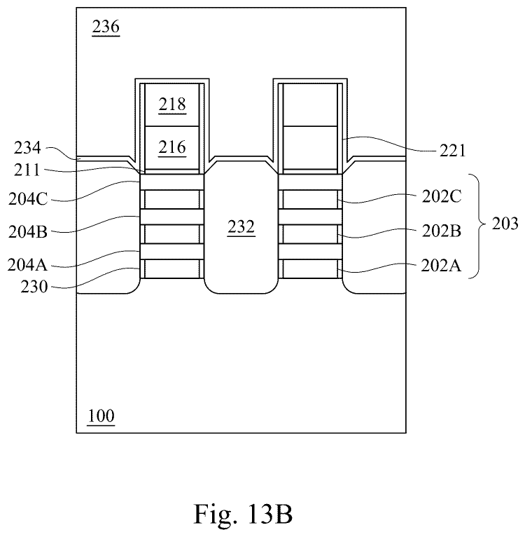

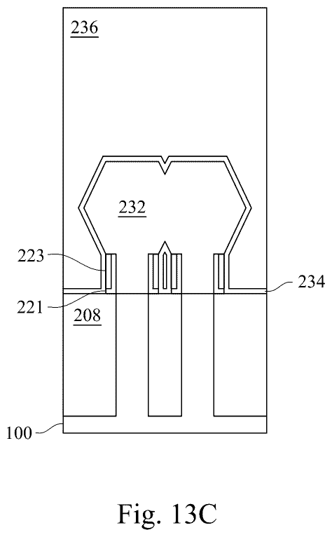

In FIGS. 13A-13C, an interlayer dielectric (ILD) layer 236 is deposited over the structure illustrated in FIGS. 12A-12D. The ILD layer 236 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 234 is disposed between the ILD layer 236 and the epitaxial source/drain regions 232, the masks 214, and the first spacers 221. The CESL 234 may comprise a dielectric material, such as, SiN, SiOₓ, SiCN, SiON, SiOCN, Al₂O₃, HfO₂, ZrO₂, HfAlOₓ, and HfSiOₓ, or the like, having a different etch rate than the material of the overlying ILD layer 236.

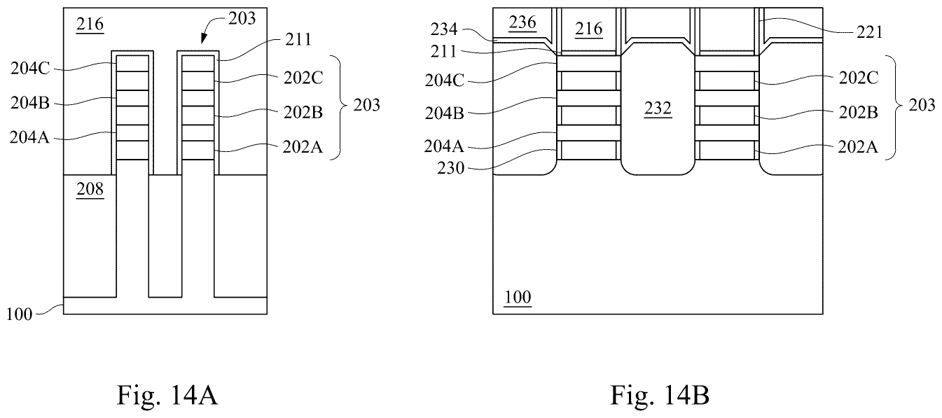

In FIGS. 14A-14B, a planarization process, such as a CMP, may be performed to level the top surface of the ILD layer 236 with the top surfaces of the dummy gates 216 or the masks 218. The planarization process may also remove the masks 218 on the dummy gates 216, and portions of the first spacers 221 along sidewalls of the masks 218. After the planarization process, top surfaces of the dummy gates 216, the first spacers 221, and the ILD layer 236 are level within process variations. Accordingly, the top surfaces of the dummy gates 212 are exposed through the ILD layer 236. In some embodiments, the masks 218 may remain, in which case the planarization process levels the top surface of the ILD layer 236 with top surface of the masks 218 and the first spacers 221.

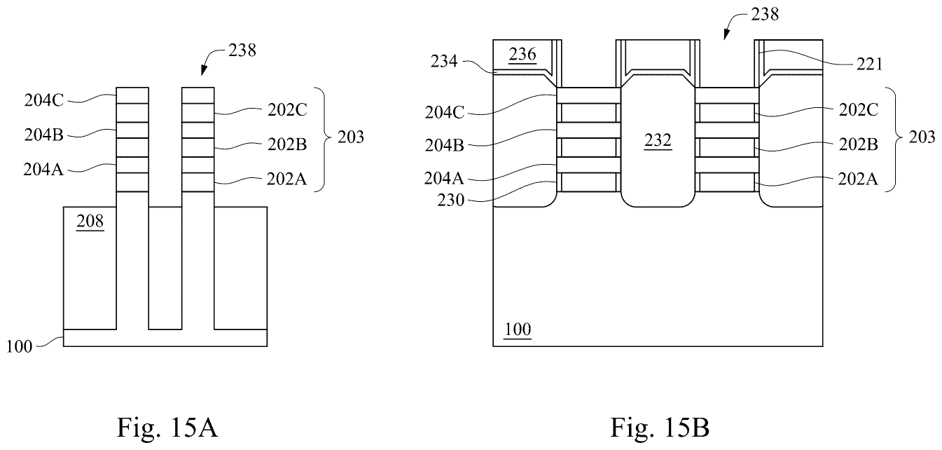

In FIGS. 15A and 15B, the dummy gates 216, and the masks 218 if present, are removed in one or more etching steps, so that gate trenches 238 are formed between corresponding gate spacers 221. In some embodiments, portions of the dummy gate dielectrics 211 in the gate trenches 238 are also be removed. In some embodiments, the dummy gates 216 and the dummy gate dielectrics 211 are removed by an anisotropic dry etch process. For example, the etching process may include a dry etch process using reaction gas(es) that selectively etch the dummy gates 216 at a faster rate than the first spacers 221. Each gate trench 238 exposes and/or overlies portions of nanostructures 204, which will serve as channel regions in subsequently completed GAA-FETs. The nanostructures 204 serving as the channel regions are disposed between neighboring pairs of the epitaxial source/drain regions 232. During the removal, the dummy dielectric layers 211 may be used as etch stop layers when the dummy gates 216 are etched. The dummy dielectric layers 211 may then be removed after the removal of the dummy gates 216.

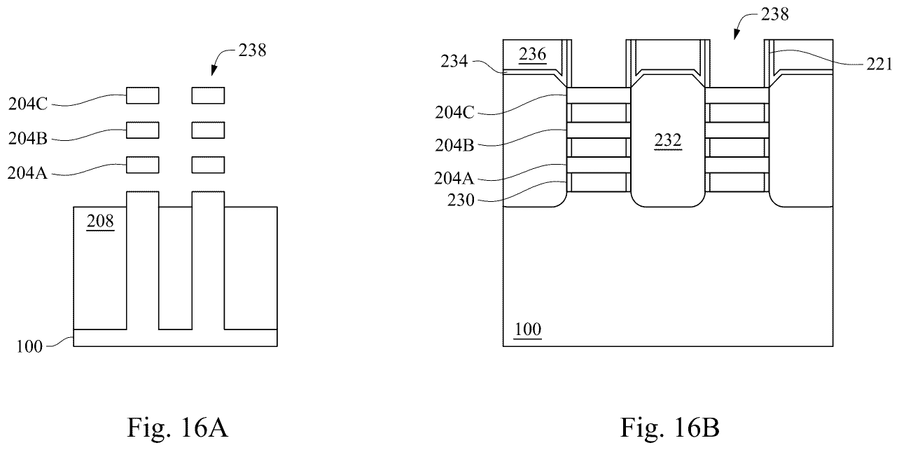

In FIGS. 16A and 16B, the first nanostructures 202 in the gate trenches 238 are removed by an isotropic etching process such as wet etching or the like using etchants which are selective to the materials of the first nanostructures 202. Stated differently, the first nanostructures 202 are removed by using a selective etching process that etches the first nanostructures 202 at a faster etch rate than it etches the second nanostructures 204, thus forming spaces between the second nanostructures 204 (also referred to as sheet-to-sheet spaces if the nanostructures 204 are nanosheets). This step can be referred to as a channel release process. At this interim processing step, the spaces between second nanostructures 204 may be filled with ambient environment conditions (e.g., air, nitrogen, etc). In some embodiments, the second nanostructures 204 can be referred to as nanosheets, nanowires, nanoslabs, nanorings having nano-scale size (e.g., a few nanometers), depending on their geometry. For example, in some embodiments the second nanostructures 204 may be trimmed to have a substantial rounded shape (i.e., cylindrical) due to the selective etching process for completely removing the first nanostructures 202. In that case, the resultant second nanostructures 204 can be called nanowires.

In embodiments in which the first nanostructures 202 include, e.g., SiGe, and the second nanostructures 204 include, e.g., Si or SiC, tetramethylammonium hydroxide (TMAH), ammonium hydroxide (NH₄OH) or the like may be used to remove the first nanostructures 202. In some embodiments, both the channel release step and the previous step of laterally recessing first nanostructures 202 (i.e., the step as illustrated in FIGS. 10A-10B) use a selective etching process that etches first nanostructures 202 (e.g., SiGe) at a faster etch rate than etching second nanostructures 204 (e.g., Si), and therefore these two steps may use the same etchant chemistry in some embodiments. In this case, the etching time/duration of channel release step is longer than the etching time/duration of the previous step of laterally recessing first nanostructures 202, so as to completely remove the sacrificial nanostructures 202.

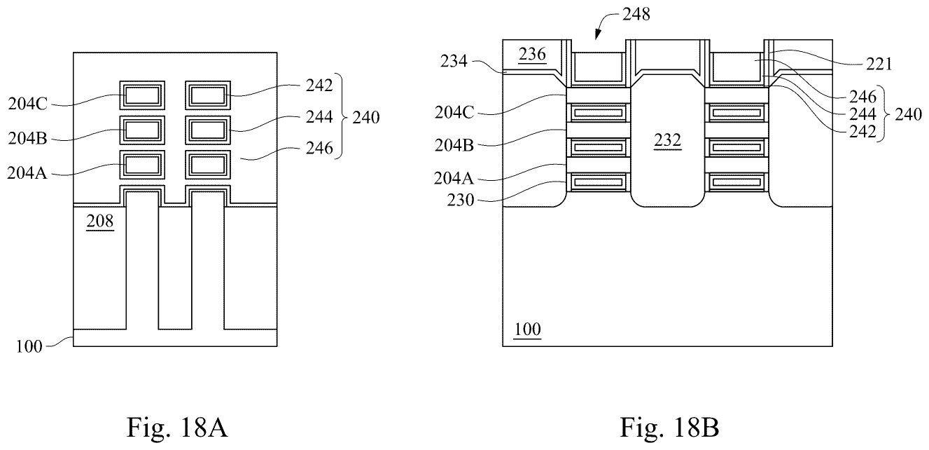

In FIGS. 17A and 17B, replacement gate structures 240 are respectively formed in the gate trenches 238 to surround each of the nanostructures 204 suspended in the gate trenches 238. The gate structures 240 may be final gates of GAA FETs. The final gate structure may be a high-k/metal gate stack, however other compositions are possible. In some embodiments, each of the gate structures 240 forms the gate associated with the multi-channels provided by the plurality of nanostructures 204. For example, high-k/metal gate structures 240 are formed within the sheet-to-sheet spaces provided by the release of nanostructures 204. In some embodiments, the gate structure 240 includes at least one dielectric layer and a metal layer which comprises a titanium-based material. In various embodiments, the high-k/metal gate structure 240 includes an interfacial layer 242 formed around the nanostructures 204, a high-k gate dielectric layer 244 formed around the interfacial layer 242, and a gate metal layer 246 formed around the high-k gate dielectric layer 244 and filling a remainder of gate trenches 238. Formation of the high-k/metal gate structures 240 may include one or more deposition processes to form various gate materials, followed by a CMP processes to remove excessive gate materials, resulting in the high-k/metal gate structures 240 having top surfaces substantially level with a top surface of the ILD layer 236. In some embodiments, the topmost surface of the gate structure 240 is non-planar a result of variations in the CMP process. In some embodiments, bottommost surfaces of the gate structure 240 at different STI regions 208 are not at same depths, because the topmost surfaces of the STI regions 208 may be non-planar and at different elevations, as illustrated in FIG. 4B. As illustrated in the cross-sectional view of FIG. 18A, the high-k/metal gate structure 240 surrounds each of the nanosheets 204, and thus is referred to as a gate of a GAA FET. Moreover, the high-k gate dielectric layer 244 and the gate metal layer 246 are formed over the nanostructures 204 and the STI regions 208. However, the interfacial layers 242 may not be formed over the STI regions 208 if these layers are created through an oxidation process.

In some embodiments, the interfacial layer 242 is silicon oxide formed on exposed surfaces of semiconductor materials in the gate trenches 238 by using, for example, thermal oxidation, chemical oxidation, wet oxidation or the like. As a result, surface portions of the nanosheets 204 exposed in the gate trenches 238 are oxidized into silicon oxide to form interfacial layer 242.

In some embodiments, the high-k gate dielectric layer 244 includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof. In some embodiments, the high-k gate dielectric layer 244 has a dielectric constant (i.e., k value) higher than that of the gate spacers 221.

In some embodiments, the gate metal layer 246 includes one or more metal layers. For example, the gate metal layer 246 may include one or more work function metal layers stacked one over another and a fill metal filling up a remainder of gate trenches 238. The one or more work function metal layers in the gate metal layer 246 provide a suitable work function for the high-k/metal gate structures 240. For an n-type GAA FET, the gate metal layer 246 may include one or more n-type work function metal (N-metal) layers. The n-type work function metal may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. On the other hand, for a p-type GAA FET, the gate metal layer 246 may include one or more p-type work function metal (P-metal) layers. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal in the gate metal layer 246 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

FIG. 17C is a top view illustrating a longitudinal end region of an example gate structure 240 in some embodiments. As illustrated in this top view, the gate structure 240 has a seam 247 present in the gate metal layer 246, and an outermost surface of the gate structure 240 is non-linear. Moreover, the interface between the gate spacer 221 and the gate structure 240 may be non-linear, such as, curved. In some embodiments, the gate spacers 221 have a thickness greater than a thickness of the high-k gate dielectric layer 244.

In FIGS. 18A and 18B, a metal gate etch back (MGEB) process is performed to etch back the gate structures 240, resulting in gate trenches 248 again between corresponding gate spacers 221. The gate trenches 248 have a smaller depth than the previous gate trenches 238 formed from dummy gate removal as illustrated in FIGS. 15A and 15B, because only upper portions of the gate structures 240 are removed. In some embodiments, the MGEB process is a selective etching process (e.g., selective dry etching, selective wet etching, or combinations thereof) that etches the materials of the high-k/metal gate structures 240 at a faster etch rate than etching other materials (e.g., spacers 221, CESL 234, and the ILD layer 236).

In FIGS. 19A and 19B, gate refill metal structures (also called gate metal caps) 254 are formed to fill respective gate trenches 248. The gate refill metal structures 254 can be formed by, for example, depositing a refill metal overfilling the gate trenches 248, followed by performing a planarization process, such as CMP, on the refill metal at least until the gate spacers 221 is exposed. Portions of the refill metal remain in the gate trenches 248 once the CMP is completed, and these remaining portions can be referred to as gate refill metal structures 254 that serve to reduce the gate resistance. In some embodiments, the gate refill metal structures 254 are tungsten (W), especially barrier-less or borderless tungsten, which can aid in resistance reduction. In this scenario, opposite sidewalls of the borderless tungsten structure 254 are in contact with opposite gate spacers 221 without barrier metals. In some embodiments, the gate refill metal structures 254 are fluorine-free tungsten (FFW) formed by, for example, PVD. The absence of fluorine in the gate refill metal structures 254 reduces the risk of fluorine-related contamination and unwanted chemical interactions within the gate structures 240. In some other embodiments, the refill metal structures 254 include, for example, Ru, Co, Cu, Mo, TaN, TiN, Ti, TiAl, the like, or combinations thereof.

FIG. 19C is a top view illustrating a longitudinal end region of an example gate structure 240 with the gate refill metal structure 254 in some embodiments. As illustrated in this top view, the gate refill metal structure 254 may cover the seam 247 within the gate metal layer 246 of the gate structure 240. In some embodiments, the interface between the gate spacer 221 and the gate refill metal structure 254 may be non-linear, such as, curved.

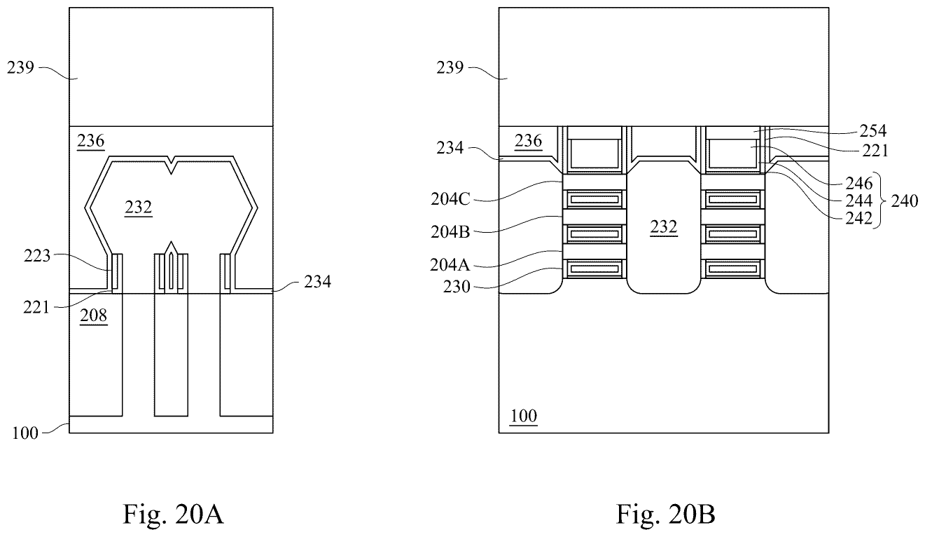

In FIGS. 20A-20B, another ILD layer 239 is formed over the ILD layer 236 and the gate refill metal structures 254. The ILD layer 239 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, the ILD layer 239 is formed of the same material as the ILD layer 236 and has a dielectric constant less than the dielectric constant of the high-k gate dielectric layer 244. In some embodiments, the dielectric constant of the high-k gate dielectric layer 244 is at least twice the dielectric constant of the ILD layer 239 and/or the ILD layer 236. In some embodiments, another CESL (not separately illustrated) is formed over the ILD layer 236 prior to forming the ILD layer 239. In some embodiments as illustrated in FIG. 20A, a maximal thickness of the ILD layer 236 measured in a vertical direction is greater than a maximal thickness of the ILD layer 239 measured in the vertical direction.

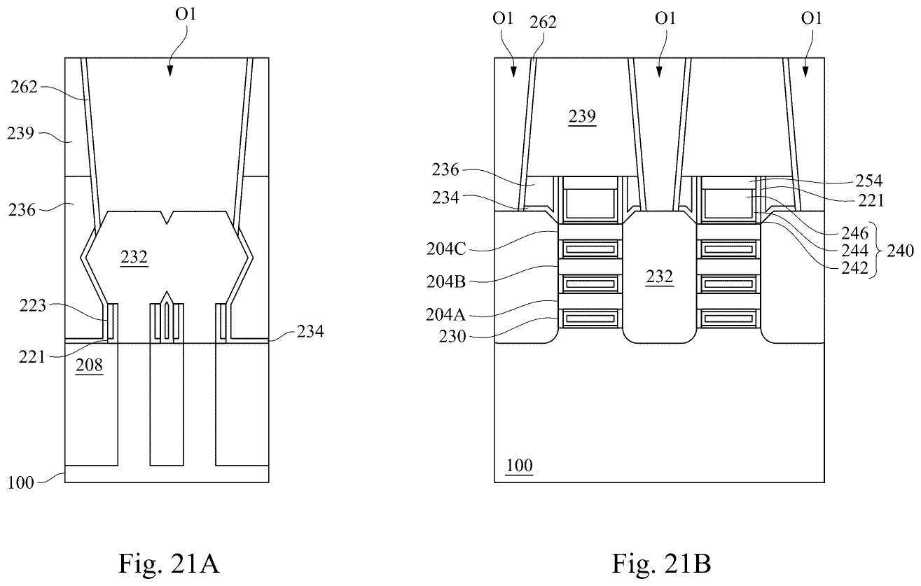

In FIGS. 21A-21B, source/drain contact openings O1 are formed extending through the ILD layer 239, the ILD layer 236, and the CESL 234 to expose the underlying epitaxial source/drain regions 232. In some embodiments, a multi-step etching process is employed to achieve the desired contact openings O1. Initially, a photolithographic process is used to define the pattern for the contact openings on the surface of the ILD layer 239. A photoresist layer is applied and exposed to UV light through a mask, followed by development to form openings at desired contact locations. Anisotropic dry etching, such as reactive ion etching (RIE) with a fluorocarbon-based plasma, etches through ILD layers 239 and 236. The CESL 234 serves as an etch stop layer due to its higher resistance. Next, the CESL 234 is etched to expose the epitaxial source/drain regions 232, using a different etching chemistry than that used for the ILD layers 239 and 239. As illustrated in FIGS. 21A and 21B, in some embodiments, a source/drain contact opening O1 may extend across two or more epitaxial source/drain regions, such as the merged source/drain regions 232 grown from adjacent fin structures 206.

Once the source/drain contact openings O1 have been formed, sacrificial liners 262 are formed lining sidewalls of the source/drain contact openings O1. In some embodiments, the sacrificial liners 262 are formed by, for example, depositing a sacrificial dielectric layer over the ILD layer 239 and into the source/drain contact openings O1, followed by removing bottom portions of the sacrificial dielectric layer by using an anisotropic etching process, while leaving portions of the sacrificial dielectric layer on the sidewalls of the source/drain contact openings O1 to serve as the sacrificial liners 262. The sacrificial liners 262 will be selectively removed from the source/drain contact openings O1 during later processing to create air gaps around the subsequently formed source/drain contacts. These liners 262 are made of a material different from the ILD layers 239 and 236, the CESL 234, and the epitaxial source/drain regions 232, allowing for etch selectivity between the sacrificial liners 262 and other surrounding materials including the ILD layers 239 and 236, the CESL 234, and the epitaxial source/drain regions 232. In some cases where the ILD layers 239 and 236 are made of an oxide-based dielectric such as silicon oxide and the CESL 234 is made of a nitride-based material such as silicon nitride, the sacrificial liners 262 may be formed of a carbon-based material such as amorphous carbon, silicon carbide or silicon oxycarbide, which is different from the oxide-based material of ILD layers 239 and 236, and the nitride-based material of the CESL 234.

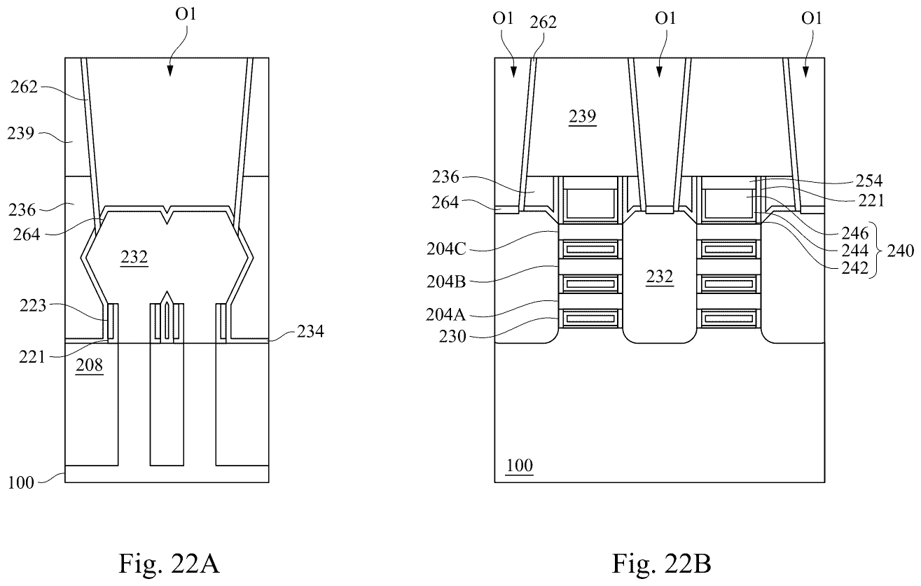

In FIGS. 22A and 22B, silicide layers 264 are formed at portions of the epitaxial source/drain regions 232 exposed at bottoms of the source/drain contact openings O1. The silicide layers 264 can be formed by depositing a metal, such as Ni, Co or Ti, on the exposed portions of the epitaxial source/drain regions 232, performing an annealing process that causes the metal to selectively react with the exposed portions of the epitaxial source/drain regions 232, followed by removing unreacted portions of the metal, leaving the metal silicide layers 264, respectively on the epitaxial source/drain regions 232. In some embodiments, the electrical conductivity of the silicide layers 264 is greater than the electrical conductivity of the epitaxial source/drain regions 232, and less than the electrical conductivity of the subsequently formed source/drain contacts. In some embodiments, the silicide layer 264 includes a non-planar profile, such as a curved profile.

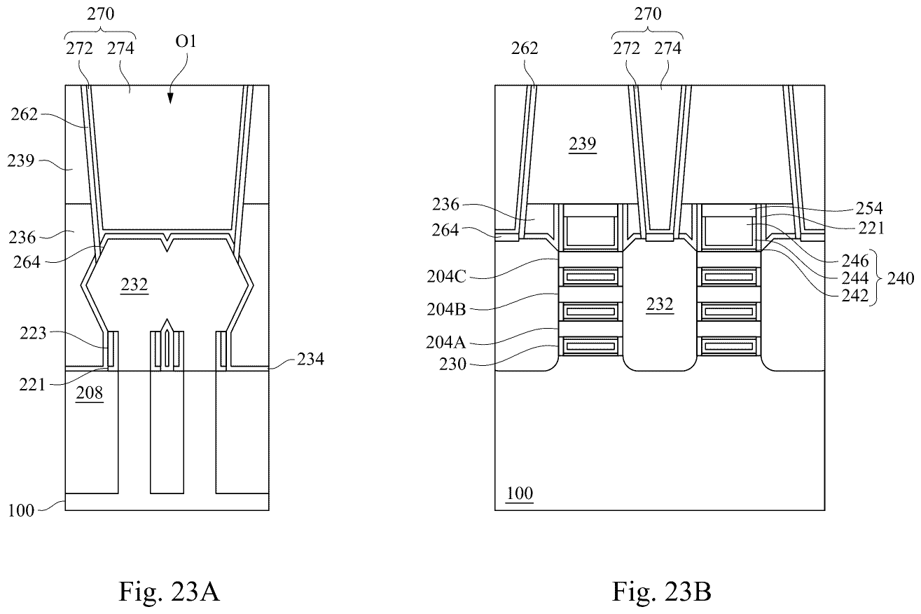

In FIGS. 23A and 23B, source/drain contacts 270 are formed in the source/drain contact openings O1 and surrounded by the ILD layers 236 and 239. In some embodiments, the source/drain contacts 270 are formed by depositing one or more metal layers, including a metal liner layer 272 and a filling metal 274 overfilling the source/drain contact openings O1, and then performing a CMP process to remove excessive metal materials outside the source/drain contact openings O1. In some embodiments, the metal liner layer 272 and the filling metal 274 are formed of different metal materials. For example, the metal liner layer 272 may include TiN or TaN, and the filling metal 274 may include tungsten, ruthenium, copper, or the like. In some embodiments, the electrical conductivity of the source/drain contacts 270 is greater than the electrical conductivity of the silicide layers 264.

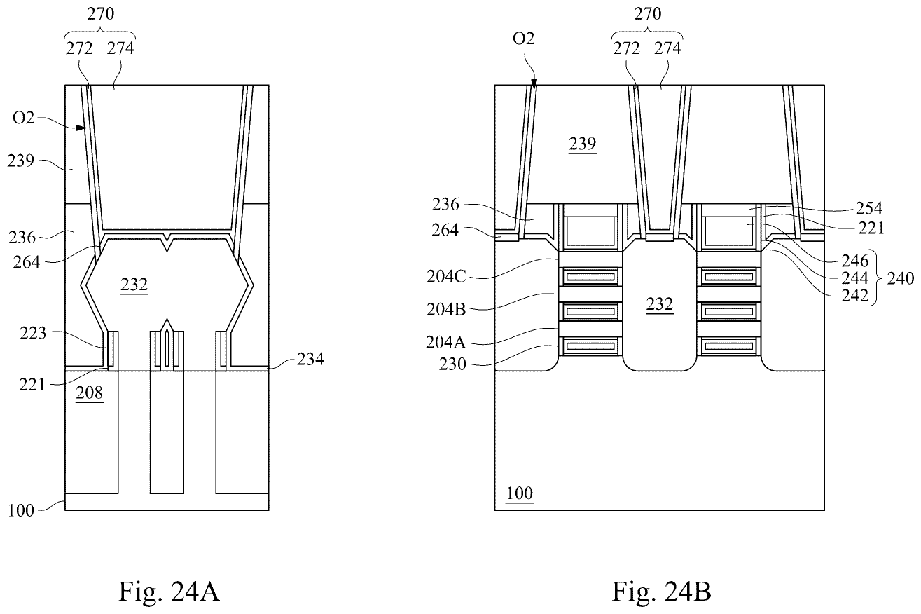

In FIGS. 24A and 24B, the dummy liners 262 are removed by using a selective etching process that etching the material of the dummy liners 262 at a faster etch rate than etching the materials of the ILD layers 239 and 236. The selective removal of the dummy liners 262 leaves air gaps O2 around the source/drain contacts 270. Specifically, by removing the material of the dummy liners 262, voids are created in the regions previously occupied by the dummy liners 262, effectively forming air gaps O2 at opposite sides of each source/drain contact 270. This process is illustrated in FIGS. 24A and 24B, which shows the air gaps O2 formed adjacent to the source/drain contacts 270 following the removal of the dummy liners 262. The formation of the air gaps O2 can contribute to a reduction in parasitic capacitance associated with the source/drain contacts 270 and adjacent conductive structures or interconnect structures. Air has a dielectric constant of approximately 1.0, which is significantly lower than that of solid dielectric materials used in ILD layers 236 and 239. By incorporating air gaps O2 around the source/drain contacts 270, the effective dielectric constant in the vicinity of the source/drain contacts 270 is lowered, leading to decreased capacitive coupling between conductive structures.

The selective etching process may involve the use of an etchant that preferentially reacts with the material of the dummy liners 262 while minimally affecting the ILD layers 239 and 236. For example, when the dummy liners 262 are formed of silicon nitride and the ILD layers 239 and 236 are formed of silicon oxide, an etchant such as phosphoric acid can be utilized. Hot phosphoric acid has a higher etch rate for silicon nitride compared to silicon oxide, allowing for the removal of the dummy liners 262 without substantially etching the ILD layers 239 and 236.

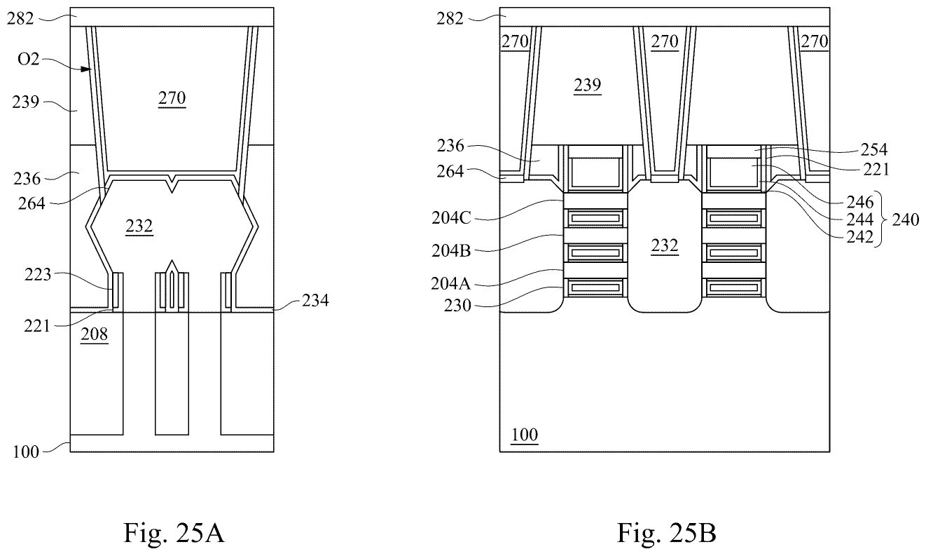

FIGS. 25A-27B illustrate processing steps of forming a multi-layered middle contact etch stop layer (also called MCESL) 280, which includes a first sub-layer 282 formed over the ILD layer 239 and the source/drain contacts 270, and a second sub-layer 284 formed over the first sub-layer 282. The MCESL 280 functions as an etch stop layer during subsequent etching processes, providing protection to underlying structures and aiding in the precise formation of via structures.

As depicted in FIGS. 25A and 25B, the first sub-layer 282 is formed over the ILD layer 239 and the source/drain contacts 270 by utilizing a suitable deposition technique. The deposition of the first sub-layer 282 may be achieved through methods such as chemical vapor deposition (CVD), plasma-enhanced chemical vapor deposition (PECVD), atomic layer deposition (ALD), physical vapor deposition (PVD), sputtering, or other appropriate thin-film deposition process. The first sub-layer 282 may comprise a material selected for its etch selectivity and compatibility with both the ILD layer 239 and the source/drain contacts 270. Materials suitable for the first sub-layer 282 include, but are not limited to, silicon nitride (SiN), silicon carbide (SiC), silicon carbon nitride (SiCN), silicon oxynitride (SiON), aluminum oxide (Al₂O₃), or other suitable dielectric materials.

The thickness of the first sub-layer 282 may be controlled based on factors such as the implant energy used in the subsequent seal implantation process to induce swelling in the ILD layer 239. A thicker first sub-layer 282 requires higher implant energy to achieve sufficient swelling in the ILD layer 239. However, using higher implant energy can affect the electrical insulation properties (e.g., leakage current density) of the first sub-layer 282 and increase the likelihood of elevated channel resistance. Therefore, the thickness of the first sub-layer 282 is kept below a predetermined threshold to minimize the impact on its electrical insulation properties and reduce the risk of increasing channel resistance. In some embodiments, the thickness of the first sub-layer 282 is in a range from about 3 nm to about 6 nm. In some embodiments, the thickness of the first sub-layer 282 may be less than the thickness of the CESL 234, as the CESL 234 is not influenced by implant energy considerations. In some embodiments, the thickness of the first sub-layer 282 is less than the thickness of the ILD layer 239 and/or the ILD layer 236.

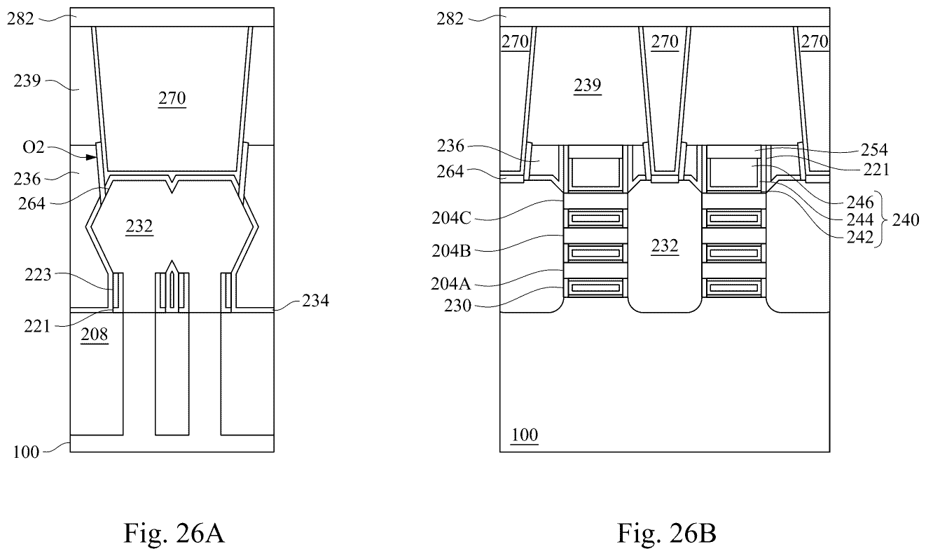

In FIGS. 26A and 26B, a seal implantation process is performed on the first sub-layer 282 of MCESL 280. Implantation energy is controlled such that ions penetrate through the first sub-layer 282 into the ILD layer 239 to induce swelling in the ILD layer 239, thereby sealing upper portions of the air gaps O2 that were previously formed in the ILD layer 239. The seal implantation process involves exposing the first sub-layer 282 to an ambience wherein ions are accelerated toward the surface of the first sub-layer 282 under controlled implant energy conditions. The implant energy is carefully regulated to allow that the ions have sufficient energy to penetrate through the thickness of the first sub-layer 282 and enter into the underlying ILD layer 239. The implant energy values may be selected based on factors such as the materials of the first sub-layer 282 and the ILD layer 239, the thicknesses of these layers, and the desired depth of ion penetration.

As the ions penetrate into the ILD layer 239, they interact with the material of the ILD layer 239, which may be a silicon oxide-based dielectric or other suitable low-k dielectric materials. The interaction between the implanted ions and the ILD material induces localized swelling or expansion within the ILD layer 239. This swelling effect is attributed to phenomena such as the formation of implanted ion clusters, defects, or other structural changes within the dielectric matrix of the ILD layer 239. The extent of the swelling can be controlled by adjusting the implant dose, which determines the concentration of implanted ions within the ILD layer 239.

The induced swelling in the ILD layer 239 effectively seals the upper portions of the air gaps O2 that were previously formed within the ILD layer 239. The swelling causes the dielectric material adjacent to the air gaps O2 to expand and close off the openings at the top of the air gaps O2. This sealing mechanism provides a barrier that inhibits the ingress of unwanted materials, such as conductive metals, chemicals, or contaminants, into the air gaps during subsequent fabrication steps. By sealing the air gaps O2, the structural integrity and reliability of the semiconductor device are enhanced, and the beneficial properties of the air gaps O2, such as reduced parasitic capacitance and improved electrical performance, are preserved.

The ion species used in the seal implantation process may include, but are not limited to, germanium-containing gases, noble gases such as helium or neon, or other species capable of inducing the desired swelling effect in the ILD layer 239. Germanium-containing ions, for example, can be sourced from gases like germane (GeH₄) and are selected for their ability to interact effectively with the ILD material 239. The selection of the ion species may depend on considerations such as the compatibility with the ILD material 239, and the effectiveness in inducing swelling.

Upon experiencing the seal implantation process, the material property of the first sub-layer 282 of the MCESL 280 may change. For example, the first sub-layer 282 may be doped with the chemical element of the ion species, such as germanium, helium, neon, or other chemical elements capable of inducing the desired swelling effect in the ILD layer 239. Moreover, the first sub-layer 282 may experience swelling due to the implantation process, which can result in it having a lower density compared to a subsequently formed second sub-layer 284. The swelling of the first sub-layer 282 is a result of ion implantation-induced expansion, similar to the swelling induced in the ILD layer 239.

As illustrated in FIGS. 26A and 26B, after the seal implantation process is completed, the air gaps O2 have top ends slightly higher than the top surface of the ILD layer 236. In some embodiments, the top ends of the air gaps O2 may have a non-linear or non-planar profile, such as a curved profile.

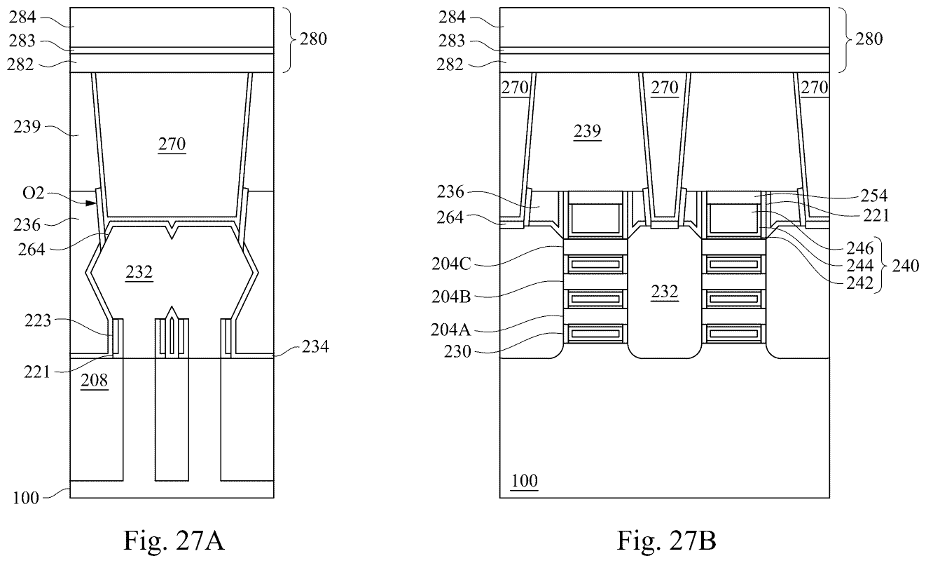

In FIGS. 27A and 27B, a second sub-layer 284 of the MCESL 280 is formed over the first sub-layer 282 of the MCESL 280. Because the second sub-layer 284 is deposited over the first sub-layer 282 after the seal implantation step, a vacuum break may occur between the deposition of the first sub-layer 282 and the deposition of the second sub-layer 284. The term “vacuum break” refers to the interruption of the vacuum environment within the processing chamber, so as to transfer the substrate 100 to a different chamber for the seal implantation process. As a result of the vacuum break, the surface of the first sub-layer 282 may be exposed to ambient atmospheric conditions, including exposure to gases such as oxygen and moisture present in the air.

This exposure can lead to the formation of a native oxide layer 283 on the surface of the first sub-layer 282 prior to the deposition of the second sub-layer 284. The native oxide layer 283 is a thin film of oxide that naturally forms on the surface of certain materials, particularly silicon-based materials, when exposed to oxygen or air. For example, if the first sub-layer 282 comprises a silicon-containing material such as silicon nitride (SiN), silicon carbide (SiC), silicon carbon nitride (SiCN), or silicon oxynitride (SiON), exposure to ambient conditions can result in the oxidation of the surface layer, forming silicon dioxide (SiO₂) atop the first sub-layer 282.

The second sub-layer 284 is then deposited over the first sub-layer 282 (and any existing native oxide layer 283). The second sub-layer 284 may be formed using deposition techniques such as chemical vapor deposition (CVD), plasma-enhanced chemical vapor deposition (PECVD), or atomic layer deposition (ALD), similar to those used for the first sub-layer 282. Example materials for the second sub-layer 284 include silicon nitride (SiN), silicon carbon nitride (SiCN), or combinations thereof. In some embodiments, both the second sub-layer 284 and the first sub-layer 282 are silicon nitride, but the second sub-layer 284 is free of the implantation species derived from the seal implantation process.

Because the second sub-layer 284 is deposited after the seal implantation step and any potential changes to the first sub-layer 282 resulting from the seal implantation step, there may be differences in material properties between the first and second sub-layers 282 and 284. The first sub-layer 282 may have incorporated implanted ion species such as germanium, helium, neon, or other elements introduced during the seal implantation process. The incorporation of these ion species can lead to changes in the chemical composition, physical structure, and density of the first sub-layer 282. For example, the first sub-layer 282 may have a lower density compared to the second sub-layer 284 due to the swelling effect caused by ion implantation.

The second sub-layer 284, being deposited after the seal implantation process, is not subjected to the same seal implantation process and therefore may not contain the implanted ion species. For example, the second sub-layer 284 may be silicon nitride free of germanium, helium, or neon. The second sub-layer 284 may have a higher density than the first sub-layer 282, because the density of the first sub-layer 282 may be reduced in the seal implantation process. Moreover, the second sub-layer 284 may have a better electrical insulation property (e.g., lower leakage current density) than the first sub-layer 282, because the electrical insulation property of the first sub-layer 282 may be degraded by the seal implantation process.

In some embodiments, the second sub-layer 284 has a thickness greater than the thickness of the first sub-layer 282. The increased thickness of the second sub-layer 284 allows that the overall thickness of the MCESL 280 is adequate to serve as an etch stop layer during subsequent etching processes used to form source/drain vias, while keeping the first sub-layer 282 thin enough to reduce the seal implantation energy. In some embodiments, a thickness ratio of the second sub-layer 284 to the first sub-layer 282 is in a range from about 1 to about 3. In some embodiments, the thickness of the second sub-layer 284 is in a range from about 3 nm to about 9 nm. In some embodiments, both thicknesses of the first sub-layer 282 and the second sub-layer 284 are greater than a thickness of the native oxide layer 283. In some embodiments, the thickness of the native oxide layer 283 is in a range from about 1 nm to about 2 nm.

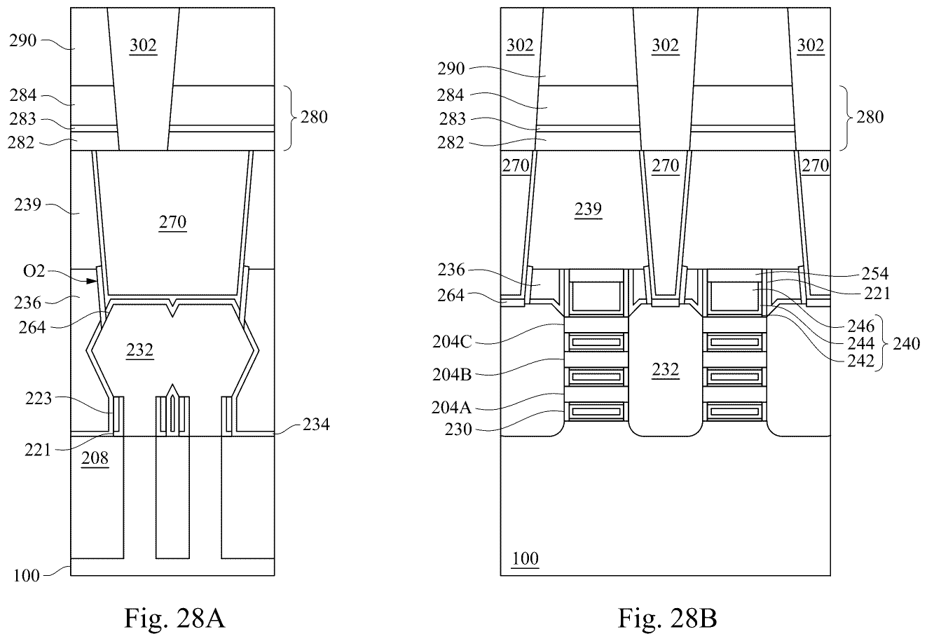

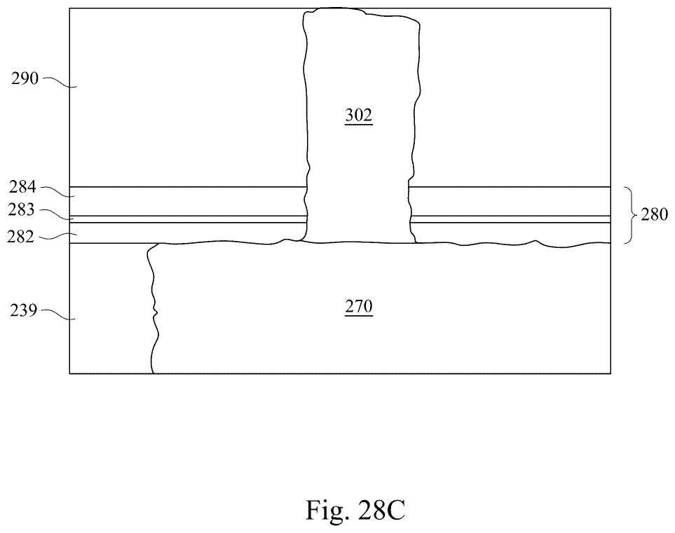

In FIGS. 28A-28B, another ILD layer 290 is formed over the MCESL 280. The ILD layer 290 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, the ILD layer 290 is formed of the same material as the ILD layer 239 and/or the ILD layer 236, and ILD layer 290 has a dielectric constant less than the dielectric constant of the high-k gate dielectric layer 244. In some embodiments, the dielectric constant of the high-k gate dielectric layer 244 is at least twice the dielectric constant of the ILD layer 290.

Next, source/drain vias 302 are formed extending through the ILD layer 290 the MCESL 280 to the source/drain contacts 270. Formation of the source/drain vias 302 includes, by way of example and not limitation, performing one or more etching processes to form via openings extending though the ILD layer 290 and the MCESL 280 to expose the source/drain contacts 270, depositing one or more metal materials (e.g., Cu, Ti, TiN, Ta, TaN, W, Ru, Mo, Ni, the like or combinations thereof) overfilling the via openings, and then performing a CMP process to remove excessive metal materials outside the via openings.

As shown in FIGS. 28A and 28B, the source/drain vias 302 have inverted trapezoidal cross-sectional patterns, and the source/drain contacts 270 also have inverted trapezoidal cross-sectional patterns. In some embodiments, the sidewall slope of the inverted trapezoidal cross-sectional pattern of the source/drain via 302 differs from that of the source/drain contact 270. This difference arises because the source/drain contacts 270 and the source/drain vias 302 are formed through separate, independent etching steps.

FIG. 28C is a zoomed-in cross-sectional view illustrating example profiles of a source/drain contact 270 and a source/drain via 302. As illustrated in FIG. 28C, the source/drain contact 270 has a non-linear sidewall. This non-linear sidewall profile may arise from the etching step for forming the contact opening in the ILD layer 239. Due to the non-linear sidewall profile, the source/drain contact 270 can form non-linear interfaces with sidewalls of the ILD layer 239. Moreover, the source/drain contact 270 may have a non-linear or non-planar top surface. This non-linear profile may arise from the variations of the CMP process performed to remove the material of the source/drain contact 270. Therefore, the first sub-layer 282 may form a non-linear interface with the source/drain contact 270. In some embodiments, the source/drain via 302 has a non-linear sidewall. This non-linear sidewall profile may arise from the etching step for forming the via opening in the ILD layer 290. Due to the non-linear sidewall profile, the source/drain via 302 can form non-linear interfaces with sidewalls of the first sub-layer 282, the native oxide layer 283, the second sub-layer 284, and the ILD layer 290. In some embodiments, the source/drain via 302 has a non-linear or non-planar top surface. This non-linear profile may arise from the variations of the CMP process performed to remove the material of the source/drain via 302.

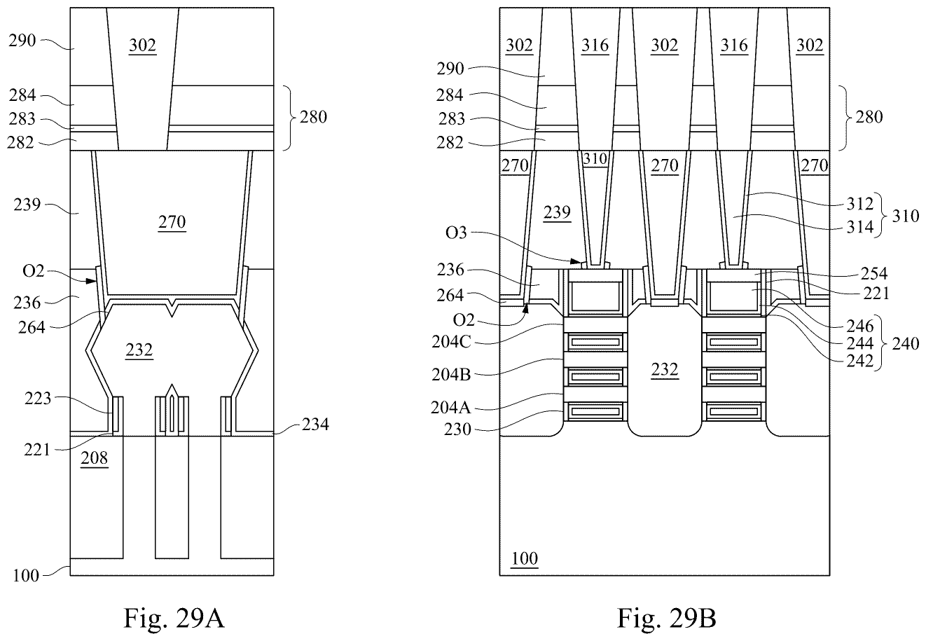

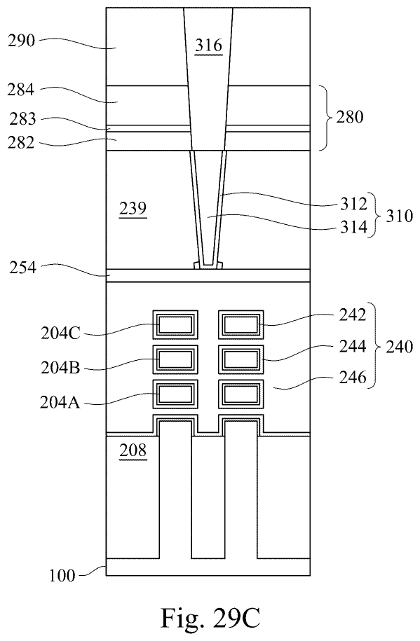

FIGS. 29A-29C are cross-sectional views of GAA-FETs, in accordance with some embodiments of the present disclosure. FIG. 29A illustrates reference cross-section C-C′ illustrated in FIG. 1 that extends through source/drain regions along the longitudinal direction of the gate region. FIG. 29B illustrates reference cross-section B-B′ illustrated in FIG. 1 that extends through a fin along a longitudinal axis of the fin. FIG. 29C illustrates reference cross-section A-A′ illustrated in FIG. 1 that extends through a gate region along a longitudinal axis of the gate region. FIGS. 29A-29C shows substantially the same structure as that shown in FIGS. 28A-28B, except that the structure shown in FIGS. 29A-29C further includes gate contacts 310 formed over the gate refill metal structures 254, and gate vias 316 formed over the gate contacts 310.

In some embodiments, the gate contacts 310 are formed simultaneously with formation of the source/drain contacts 270 and hence include the same material composition as the source/drain contacts 270. For example, the gate contact 310 includes a metal liner layer 312 and a filling metal 314 with sidewalls and a bottom surface lined by the metal liner layer 312. The metal liner layer 312 has the same material as the metal liner layer 272 of the source/drain contact 270, and the filling metal 314 has the same material as the filling metal 274 of the source/drain contact 270. In some embodiments, the metal liner layer 312 may include TiN or TaN, and the filling metal 314 may include tungsten, ruthenium, copper, or the like. In some embodiments, the electrical conductivity of the gate contacts 310 is greater than the electrical conductivity of the silicide layers 264.

Formation of the gate contacts 310 include etching gate contact openings in the ILD layer 239 concurrently with the etching of source/drain contact openings in the ILD layer 239, depositing one or more metal layers overfilling the gate contact openings, followed by performing a CMP process to remove excessive metal materials outside the gate contact openings. In some embodiments, air gaps O3 are formed around the gate contacts 310. The air gaps O3 are formed simultaneously with the formation of the air gaps O2 around the source/drain contacts 270, and sealed simultaneously with the seal implantation step for sealing the air gaps O2. For example, the air gaps O3 can be formed by, for example, depositing sacrificial liners lining sidewalls of the gate contact openings, depositing the materials of the gate contacts 310 into the gate contact openings, performing a CMP process to remove excessive materials of the gate contacts 310 outside the gate contact openings, followed by removing the sacrificial liners from the gate contact openings.

In some embodiments, the gate vias 316 are formed simultaneously with formation of the source/drain vias 302 and hence include the same material composition as the source/drain vias 302. For example, the gate vias 316 may include Cu, Ti, TiN, Ta, TaN, W, Ru, Mo, Ni, the like or combinations thereof. Formation of the gate vias 316 includes, by way of example and not limitation, performing one or more etching processes to form via openings extending though the ILD layer 290 and the MCESL 280 to expose the gate contacts 310, overfilling the via openings, and then performing a CMP process to remove excessive metal materials outside the via openings. In some embodiments, the gate vias 316 may form non-linear interfaces with sidewalls of the first sub-layer 282, the native oxide layer 283, the second sub-layer 284, and the ILD layer 290.

Some embodiments described above pertain to gate-all-ground field-effect transistors (GAA-FETs). Furthermore, some embodiments pertain to fin field-effect transistors (FinFETs), as detailed below.

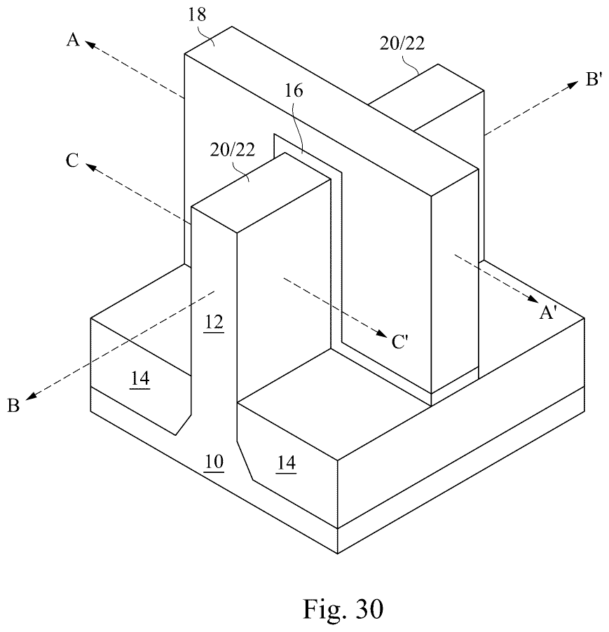

FIG. 30 illustrates an example of a FinFET in a three-dimensional view, in accordance with some embodiments. The FinFET comprises a fin 12 on a substrate 10 (e.g., a semiconductor substrate). Isolation regions 14 are disposed in the substrate 10, and the fin 12 protrudes above and from between neighboring isolation regions 14. Although the isolation regions 14 are described/illustrated as being separate from the substrate 10. Additionally, although the fin 12 is illustrated as a single, continuous material as the substrate 10, the fin 12 and/or the substrate 10 may comprise a single material or a plurality of materials. In this context, the fin 12 refers to the portion extending between the neighboring isolation regions 14.

A gate dielectric layer 16 is along sidewalls and over a top surface of the fin 12 and a gate electrode 18 is over the gate dielectric layer 16. Source/drain regions 20 or 22 are disposed in opposite sides of the fin 12 with respect to the gate dielectric layer 16 and gate electrode 18. FIG. 30 further illustrates reference cross-sections that can be used in later figures. Cross-section A-A′ is along a longitudinal axis of the gate electrode 18 and in a direction, for example, perpendicular to the direction of current flow between the source/drain regions 20/22 of the FinFET. Cross-section B-B′ is perpendicular to cross-section A-A′ and is along a longitudinal axis of the fin 12 and in a direction of, for example, a current flow between the source/drain regions 20/22 of the FinFET. Subsequent figures refer to these reference cross-sections for clarity. Cross-section C-C′ is parallel to cross-section A-A′ and extends through a source/drain region of the FinFET. Subsequent figures refer to these reference cross-sections for clarity.

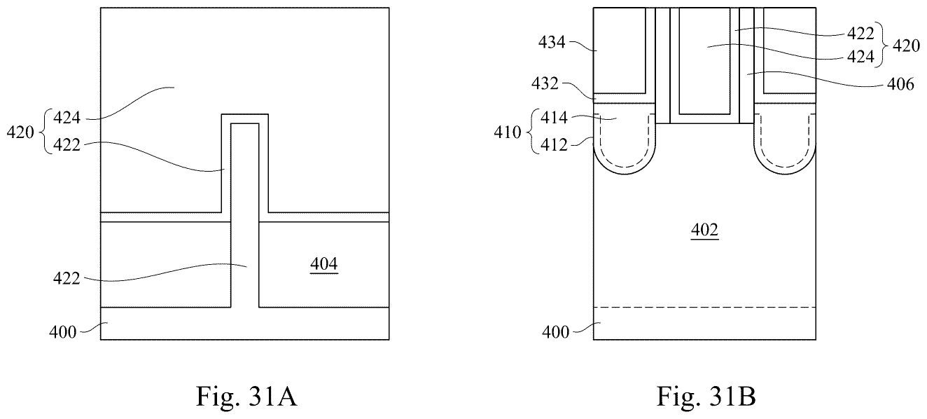

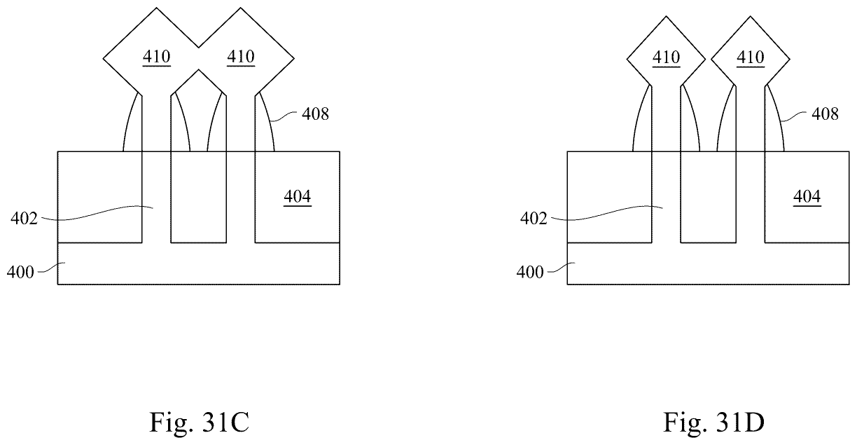

FIGS. 31A-40 illustrate cross-sectional views of intermediate stages in the manufacturing of FinFETs in accordance with some exemplary embodiments. FIGS. 31A, 32A, and 33A illustrate reference cross-section A-A′ illustrated in FIG. 30. FIGS. 31B, 32B, 33B, and 34-40 illustrate reference cross-section B-B′ illustrated in FIG. 30. FIGS. 31C and 31D illustrate reference cross-section C-C′ illustrated in FIG. 30. Throughout the various views and illustrative embodiments, like reference numbers are used to designate like elements. It is understood that additional operations can be provided before, during, and after the processes shown by FIGS. 31A-40, and some of the operations described below can be replaced or eliminated, for additional embodiments of the method. The order of the operations/processes may be interchangeable.

In FIGS. 31A-31B, a fin structure 402 is formed on a substrate 400. The substrate 400 may be a semiconductor substrate, such as a bulk semiconductor, a semiconductor-on-insulator (SOI) substrate, or the like, which may be doped (e.g., with a p-type or an n-type dopant) or undoped. Further details of the substrate 400 are similar to that of the substrate 100 discussed previously and therefore are not repeated for the sake of brevity. The fin structure 402 is formed by etching trenches in the substrate 400 by using any acceptable etch process, such as a reactive ion etch (RIE), neutral beam etch (NBE), the like, or a combination thereof. Further details of the fin structure 402 are similar to that of the fin structures 206 discussed previously and therefore are not repeated for the sake of brevity.

Shallow trench isolation (STI) regions 404 are formed adjacent the fin structure 402, with an upper portion of the fin structure 402 protrudes from between the neighboring STI regions 404. Further, the top surfaces of the STI regions 404 may have a flat surface as illustrated, a convex surface, a concave surface (such as dishing as illustrated in FIG. 4B), or a combination thereof. Further details of the STI region 404 are similar to that of the STI regions 208 discussed previously and therefore are not repeated for the sake of brevity.

Gate spacers 406 are formed on opposite sides of a gate structure 420, and fin sidewall spacers 408 are formed on opposite sides of fin structures 402. Further details of the spacers 406, 408 are similar to that of the spacers 221, 223 discussed previously and therefore are not repeated for the sake of brevity.

Epitaxial source/drain regions 410 are formed in the fin structure 402 by, for example, etching source/drain recesses in the fin structure 402, followed by epitaxially growing one or more layers of semiconductor materials in the source/drain recesses. The epitaxial source/drain regions 410 may comprise one or more semiconductor material layers, with at least two layers containing same semiconductor material with difference concentrations. For example, the epitaxial source/drain regions 410 may comprise a first semiconductor material layer 412 and a second semiconductor material layer 414, which are distinguished in FIG. 31B by using dash lines. Any number of semiconductor material layers may be used for the epitaxial source/drain regions 410. Each of the first semiconductor material layer 412 and the second semiconductor material layer 414 may be formed of same or different semiconductor materials and may be doped to different dopant concentrations. In some embodiments, the first semiconductor material layer 412 may have a dopant concentration less than the second semiconductor material layer 414. The epitaxial source/drain regions 410 are at least partially embedded in the substrate 100 and adjacent to the channel region within the fin structure 402.

Epitaxial source/drain regions 410 grown from adjacent fin structures 402 may be merged, as illustrated in FIG. 31C, or may be separated, as illustrated in FIG. 31D. In some embodiments, as illustrated in FIGS. 31C and 31D, each epitaxial source/drain region 410 has a thickness measured in a vertical direction and a width measured in a horizontal direction, and the thickness is different from the width. In some embodiments, the width of the epitaxial source/drain region 410 has the width greater than a width of the fin structure 402, such that a portion of the epitaxial source/drain region 410 overhangs the STI region 404. Further details of the epitaxial source/drain regions 410 are similar to that of the epitaxial source/drain regions 232 discussed previously and therefore are not repeated for the sake of brevity.

A gate structure 420 is formed across the channel region within the fin structure 402, and between the gate spacers 406. The gate structure 420 can be formed by, for example, forming a dummy gate across the fin structure 402 prior to forming the gate spacers 406 and the epitaxial source/drain region 410, and then replacing the dummy gate with the gate structure 420 after forming a CESL 432 and an ILD layer 434 over the epitaxial source/drain regions 232. In some embodiments, the gate structure 420 includes an interfacial layer (not separately illustrated) formed on surfaces of the fin structure 402, a high-k gate dielectric layer 422 over the high-k gate dielectric layer 422, and a gate metal layer 424 over the high-k gate dielectric layer 422. Further details of the gate structure 420, the CESL 432, and the ILD layer 434 are similar to that of the gate structure 240, the CESL 234, and the ILD layer 236 discussed previously and therefore are not repeated for the sake of brevity.

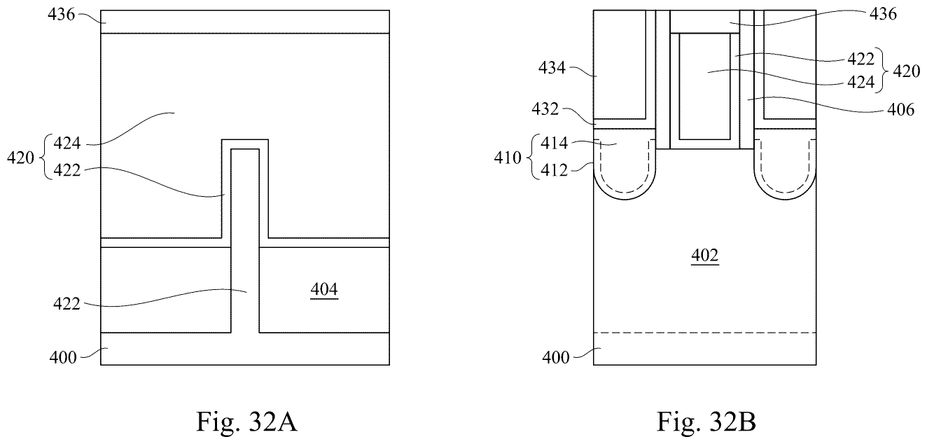

In FIGS. 32A and 32B, a gate refill metal structure 436 is formed over the gate structure 420 by, for example, etching back the gate structure 420 such that the top surface of the gate structure 420 falls below the top surfaces of the gate spacers 406, depositing a material of the gate refill metal structure 436 over the etched back gate structure 420, followed by a CMP process carried out to remove excessive material over the gate spacers 406. In some embodiments, the gate refill metal structures 254 are tungsten (W), especially barrier-less or borderless tungsten, which can aid in resistance reduction. In this scenario, opposite sidewalls of the borderless tungsten structure 254 are in contact with opposite gate spacers 221 without barrier metals. In some embodiments, the gate refill metal structures 254 are fluorine-free tungsten (FFW) formed by, for example, PVD. Further details of the gate refill metal structure 436 are similar to that of the gate refill metal structure 254 discussed previously and therefore are not repeated for the sake of brevity.

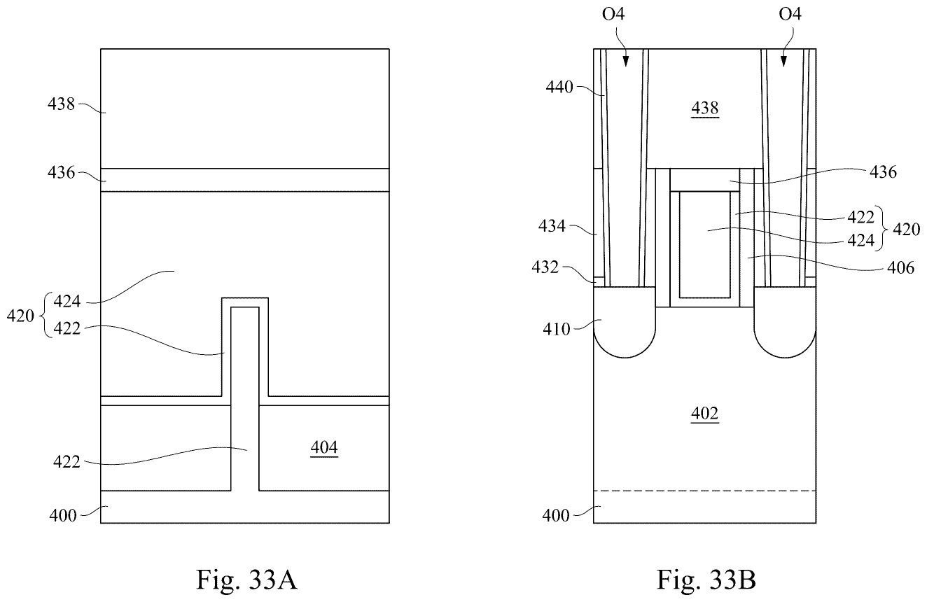

In FIGS. 33A and 33B, another ILD layer 438 is formed over the ILD layer 434 and the gate refill metal structure 436, and then source/drain contact openings O4 are formed extending through the ILD layer 434, the ILD layer 434, and the CESL 432 to expose the underlying epitaxial source/drain regions 410. In some embodiments, another CESL (not separately illustrated) is formed over the ILD layer 434 prior to forming the ILD layer 438. Next, sacrificial liners 440 are formed lining sidewalls of the source/drain contact openings O4. Further details of the ILD layer 438, the contact openings O4, and the sacrificial liners 440 are similar to that of the ILD layer 239, the contact openings O1, and the sacrificial liners 262 discussed previously and therefore are not repeated for the sake of brevity.

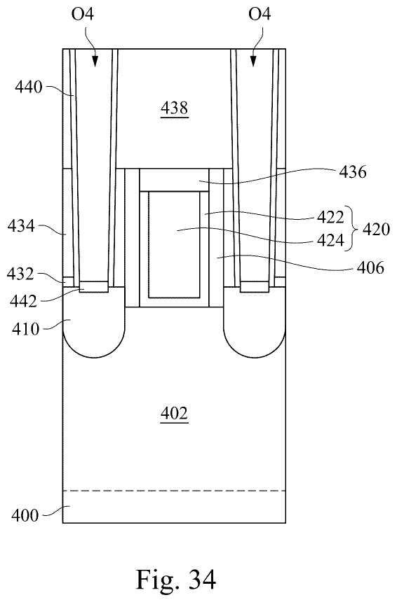

In FIG. 34, silicide layers 442 are formed at portions of the epitaxial source/drain regions 410 exposed at bottoms of the source/drain contact openings O4. Further details of the silicide layers 442 are similar to that of the silicide layers 264 discussed previously and therefore are not repeated for the sake of brevity.

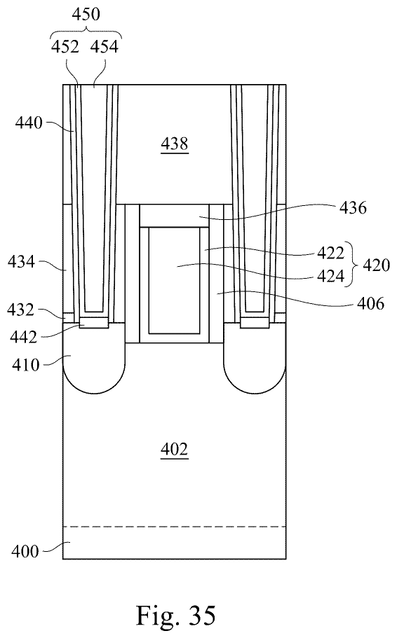

In FIG. 35, source/drain contacts 450 are formed in the source/drain contact openings O4 and surrounded by the ILD layers 438 and 434. In some embodiments, the source/drain contacts 450 are formed by depositing one or more metal layers, including a metal liner layer 452 and a filling metal 454, overfilling the source/drain contact openings O4, and then performing a CMP process to remove excessive metal materials outside the source/drain contact openings O4. Further details of the source/drain contacts 450 are similar to that of the source/drain contacts 270 discussed previously and therefore are not repeated for the sake of brevity.

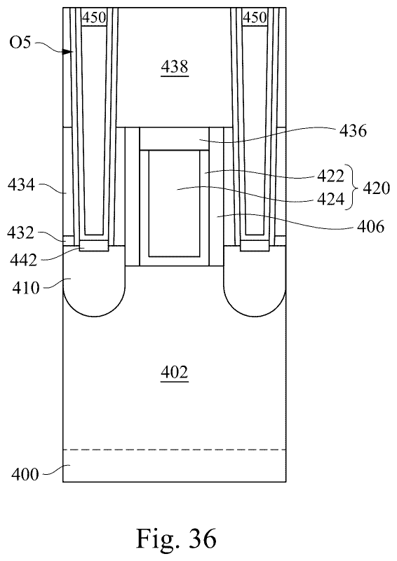

In FIG. 36, the dummy liners 440 are removed by using a selective etching process that etching the material of the dummy liners 440 at a faster etch rate than etching the materials of the ILD layers 438 and 434. The selective removal of the dummy liners 440 leaves air gaps O5 around the source/drain contacts 450. Further details of the air gaps O5 are similar to that of the air gaps O2 discussed previously and therefore are not repeated for the sake of brevity.

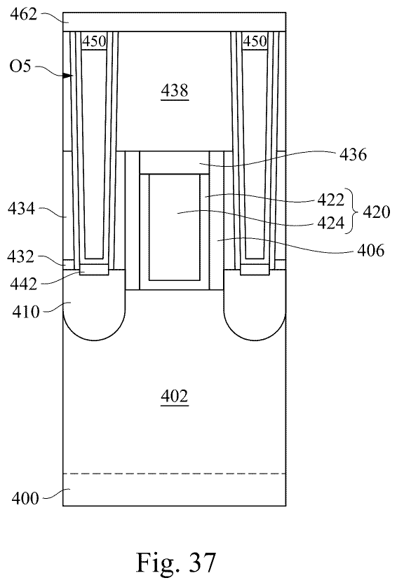

FIGS. 37-39 illustrate processing steps of forming a multi-layered middle contact etch stop layer (also called MCESL) 460, which includes a first sub-layer 462 formed over the ILD layer 438 and the source/drain contacts 450, and a second sub-layer 464 formed over the first sub-layer 462. The MCESL 460 functions as an etch stop layer during subsequent etching processes, providing protection to underlying structures and aiding in the precise formation of via structures.

As depicted in FIG. 37, the first sub-layer 462 is formed over the ILD layer 438 and the source/drain contacts 450 by utilizing a suitable deposition technique. The deposition of the first sub-layer 462 may be achieved through methods such as chemical vapor deposition (CVD), plasma-enhanced chemical vapor deposition (PECVD), atomic layer deposition (ALD), physical vapor deposition (PVD), sputtering, or other appropriate thin-film deposition process. The first sub-layer 462 may comprise a material selected for its etch selectivity and compatibility with both the ILD layer 438 and the source/drain contacts 450. Materials suitable for the first sub-layer 462 include, but are not limited to, silicon nitride (SiN), silicon carbide (SiC), silicon carbon nitride (SiCN), silicon oxynitride (SiON), aluminum oxide (Al₂O₃), or other suitable dielectric materials.

The thickness of the first sub-layer 462 may be controlled based on factors such as the implant energy used in the subsequent seal implantation process to induce swelling in the ILD layer 438. A thicker first sub-layer 462 requires higher implant energy to achieve sufficient swelling in the ILD layer 438. However, using higher implant energy can affect the electrical insulation properties (e.g., leakage current density) of the first sub-layer 462 and increase the likelihood of elevated channel resistance. Therefore, the thickness of the first sub-layer 462 is kept below a predetermined threshold to minimize the impact on its electrical insulation properties and reduce the risk of increasing channel resistance. In some embodiments, the thickness of the first sub-layer 462 is in a range from about 3 nm to about 6 nm. In some embodiments, the thickness of the first sub-layer 462 may be less than the thickness of the CESL 432, as the CESL 432 is not influenced by implant energy considerations. In some embodiments, the thickness of the first sub-layer 462 is less than the thickness of the ILD layer 438 and/or the ILD layer 434.

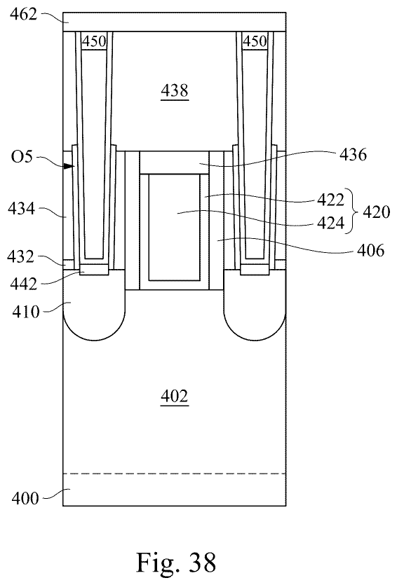

In FIG. 38, a seal implantation process is performed on the first sub-layer 462 of MCESL 460. Implant energy is controlled such that ions penetrate through the first sub-layer 462 into the ILD layer 438 to induce swelling in the ILD layer 438, thereby sealing upper portions of the air gaps O5 that were previously formed in the ILD layer 438. The ion species used in the seal implantation process may include, but are not limited to, germanium-containing gases, noble gases such as helium or neon, or other species capable of inducing the desired swelling effect in the ILD layer 438.

Upon experiencing the seal implantation process, the material property of the first sub-layer 462 of the MCESL 460 may change. For example, the first sub-layer 462 may include the chemical element of the ion species, such as germanium, helium, neon, or other chemical elements capable of inducing the desired swelling effect in the ILD layer 438. Moreover, the first sub-layer 462 may experience swelling due to the implantation process, which can result in it having a lower density compared to a subsequently formed second sub-layer 464. After the seal implantation process is completed, the air gaps O5 have top ends slightly higher than the top surface of the ILD layer 434. In some embodiments, the top ends of the air gaps O5 may have a non-linear or non-planar profile, such as a curved profile. Further details of the seal implantation process are similar to that of the seal implantation process discussed previously with respect to FIGS. 26A and 26B, and therefore are not repeated for the sake of brevity.

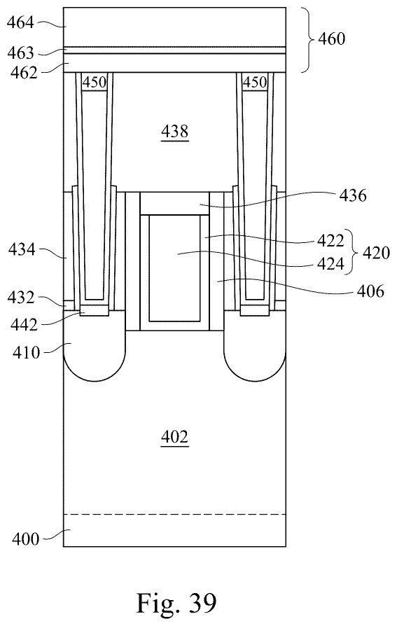

In FIG. 39, a second sub-layer 464 of the MCESL 460 is formed over the first sub-layer 462 of the MCESL 460. Because the second sub-layer 464 is deposited over the first sub-layer 462 after the seal implantation step, a vacuum break occurs between the deposition of the first sub-layer 462 and the deposition of the second sub-layer 464. As a result of the vacuum break, the surface of the first sub-layer 464 may be exposed to ambient atmospheric conditions, including exposure to gases such as oxygen and moisture present in the air. This exposure can lead to the formation of a native oxide layer 463 on the surface of the first sub-layer 462 prior to the deposition of the second sub-layer 464. The native oxide layer 463 is a thin film of oxide that naturally forms on the surface of certain materials, particularly silicon-based materials, when exposed to oxygen or air. For example, if the first sub-layer 462 comprises a silicon-containing material such as silicon nitride (SiN), silicon carbide (SiC), silicon carbon nitride (SiCN), or silicon oxynitride (SiON), exposure to ambient conditions can result in the oxidation of the surface layer, forming silicon dioxide (SiO₂) atop the first sub-layer 462. In some embodiments, example materials for the second sub-layer 464 include silicon nitride (SiN), silicon carbon nitride (SiCN), or combinations thereof. In some embodiments, both the second sub-layer 464 and the first sub-layer 462 are silicon nitride, but the second sub-layer 464 is free of the implantation species derived from the seal implantation process.

Because the second sub-layer 464 is deposited after the seal implantation step and any potential changes to the first sub-layer 462 resulting from the seal implantation step, there may be differences in material properties between the first and second sub-layers 462 and 464. The first sub-layer 462 may have incorporated implanted ion species such as germanium, helium, neon, or other elements introduced during the seal implantation process. The incorporation of these ion species can lead to changes in the chemical composition, physical structure, and density of the first sub-layer 462. For example, the first sub-layer 462 may have a lower density compared to the second sub-layer 464 due to the swelling effect caused by ion implantation.

The second sub-layer 464, being deposited after the seal implantation process, is not subjected to the same seal implantation process and therefore may not contain the implanted ion species. For example, the second sub-layer 464 may be silicon nitride free of germanium, helium, or neon. The second sub-layer 464 may have a higher density than the first sub-layer 462, because the density of the first sub-layer 462 may be reduced in the seal implantation process. Moreover, the second sub-layer 464 may have a better electrical insulation property (e.g., lower leakage current density) than the first sub-layer 462, because the electrical insulation property of the first sub-layer 462 may be degraded by the seal implantation process.

In some embodiments, the second sub-layer 464 has a thickness greater than the thickness of the first sub-layer 462. The increased thickness of the second sub-layer 464 allows that the overall thickness of the MCESL 460 is adequate to serve as an etch stop layer during subsequent etching processes used to form source/drain vias, while keeping the first sub-layer 282 thin enough to reduce the seal implantation energy. In some embodiments, a thickness ratio of the second sub-layer 464 to the first sub-layer 462 is in a range from about 1 to about 3. In some embodiments, the thickness of the second sub-layer 464 is in a range from about 3 nm to about 9 nm. In some embodiments, both thicknesses of the first sub-layer 462 and the second sub-layer 464 are greater than a thickness of the native oxide layer 463. In some embodiments, the thickness of the native oxide layer 463 is in a range from about 1 nm to about 2 nm.

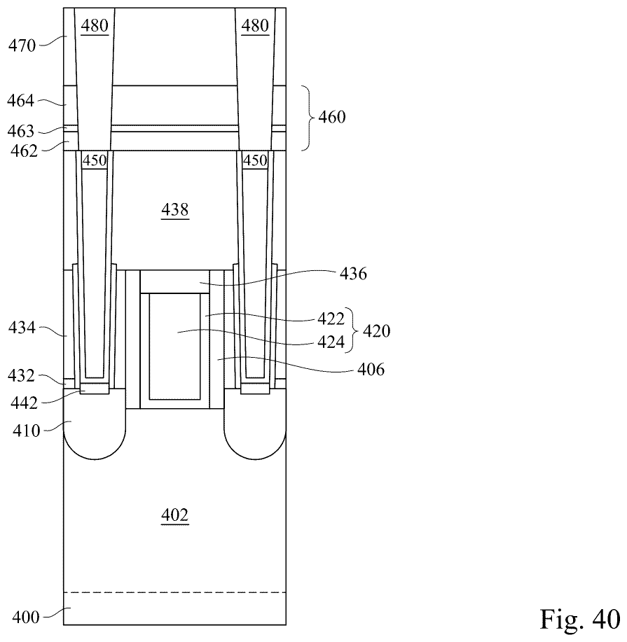

In FIG. 40, another ILD layer 470 is formed over the MCESL 460, and source/drain vias 480 are formed extending through the ILD layer and the MCESL 460 to the source/drain contacts. Further details of the ILD layer 470 and the source/drain vias 480 are similar to that of the ILD layer 290 and source/drain vias 302 discussed previously, and therefore are not repeated for the sake of brevity.

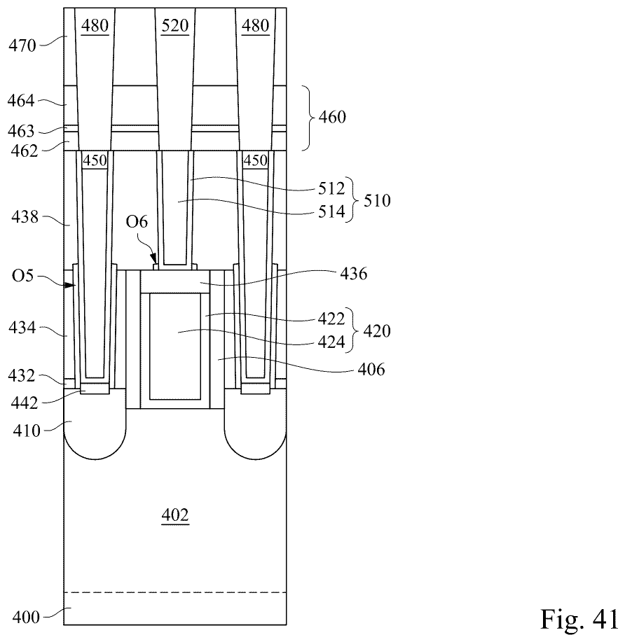

FIG. 41 is a cross-sectional view of FinFET, in accordance with some embodiments of the present disclosure. FIG. 41 shows substantially the same structure as that shown in FIG. 40, except that the structure shown in FIG. 41 further includes a gate contacts 510 formed over the gate refill metal structure 436, and a gate via 520 formed over the gate contact 510. In some embodiments, the gate contact 510 is formed simultaneously with formation of the source/drain contacts 450 and hence includes the same material composition as the source/drain contacts 450. For example, the gate contact 510 includes a metal liner layer 512 and a filling metal 514 with sidewalls and a bottom surface lined by the metal liner 512.

In some embodiments, air gaps O6 are formed around the gate contact 510. The air gaps O6 are formed simultaneously with the formation of the air gaps O5 around the source/drain contacts 270, and sealed simultaneously with the seal implantation step for sealing the air gaps O5. For example, the air gaps O6 can be formed by, for example, depositing sacrificial liners lining sidewalls of the gate contact opening, depositing the materials of the gate contact 510 into the gate contact opening, performing a CMP process to remove excessive materials of the gate contact 510 outside the gate contact openings, followed by removing the sacrificial liners from the gate contact openings.

In some embodiments, the gate via 520 is formed simultaneously with formation of the source/drain vias 480 and hence includes the same material composition as the source/drain vias 480. Further details of the gate contact 510 and the gate via 520 are similar to that of the gate contact 310 and the gate via 316 discussed previously, and therefore are not repeated for the sake of brevity.

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. One advantage is that the two-step MCESL formation technique allows for reduced implant energy to achieve effective sealing without compromising the final thickness of the MCESL, thereby preserving its role as an etch stop layer.

In some embodiments, a method includes forming a source/drain feature (e.g., epitaxial source/drain region 232 or 410) over a substrate; forming a first interlayer dielectric (ILD) layer (e.g., ILD layer 236 or 434) over the source/drain feature; forming a metal silicide layer (e.g., silicide layer 264 or 442) over the source/drain feature; forming a source/drain contact (e.g., contact 270 or 450) in the first ILD layer to electrically couple to the source/drain feature through the metal silicide layer, wherein an electrical conductivity of the metal silicide layer is between an electrical conductivity of the source/drain feature and an electrical conductivity of the source/drain contact; forming a first sub-layer (e.g., sub-layer 282 or 462) of an etch stop layer over the first ILD layer and the source/drain contact; performing an ion implantation process on the first sub-layer of the etch stop layer; after performing the ion implantation process, forming a second sub-layer (e.g., sub-layer 284 or 464) of the etch stop layer over the first sub-layer of the etch stop layer; forming a second ILD layer (e.g., ILD layer 290 or 470) over the second sub-layer of the etch stop layer; and forming a source/drain via (e.g., via 302 or 480) extending through the second ILD layer, the second sub-layer of the etch stop layer, and the first sub-layer of the etch stop layer to the source/drain contact. In some embodiments, the method further includes forming an air gap in the first ILD layer. In some embodiments, after the ion implantation process, the air gap has a top end lower than a top surface of the first ILD layer. In some embodiments, after the ion implantation process, the first sub-layer of the etch stop layer comprises an implantation species derived from the ion implantation process. In some embodiments, the second sub-layer of the etch stop layer is free of the implantation species derived from the ion implantation process. In some embodiments, the second sub-layer of the etch stop layer is in contact with an oxide formed on the first sub-layer of the etch stop layer. In some embodiments, the oxide is thinner than the second sub-layer of the etch stop layer, and/or thinner than the first sub-layer of the etch stop layer. In some embodiments, the source/drain via forms a non-linear interface with the second sub-layer of the etch stop layer, the oxide, and the first sub-layer of the etch stop layer. In some embodiments, the first sub-layer of the etch stop layer is thinner than the second sub-layer of the etch stop layer.

In some embodiments, a method includes forming a channel region (e.g., nanostructure 204 or fin structure 402) over a substrate; forming a silicon-containing structure (e.g., epitaxial source/drain region 232 or 410) having a first semiconductor layer (e.g., first semiconductor material layer 232A or 412) adjacent to the channel region and a second semiconductor layer (e.g., second semiconductor material layer 232B or 414) spaced apart from the channel region by the first semiconductor layer, wherein a composition of the first semiconductor layer is different from a composition of the second semiconductor layer, wherein a thickness of the silicon-containing structure is different from a width of the silicon-containing structure in a cross-sectional view, as shown in FIGS. 12A, 12C, 31C, or 31D; forming a first ILD layer (e.g., ILD layer 236 or 434) over the silicon-containing structure; forming a source/drain contact (e.g., contact 270 or 450) extending through the first ILD layer to electrically couple to the silicon-containing structure; forming a multi-layered etch stop layer (e.g., MCESL 280 or 460) over the source/drain contact, the multi-layered etch stop layer comprising a first nitride layer (e.g., sub-layer 282 or 462), a second nitride layer (e.g., sub-layer 284 or 464), and an oxide layer (e.g., oxide layer 283 or 463) interposing the first nitride layer and the second nitride layer, wherein the oxide layer has a thickness less than a thickness of the second nitride layer; forming a second ILD layer (e.g., ILD layer 290 or 470) over the multi-layered etch stop layer; and forming a via structure (e.g., source/drain via 302 or 480) extending through the second ILD layer and the multi-layered etch stop layer to the source/drain contact. In some embodiments, the thickness of the oxide layer is less than a thickness of the first nitride layer. In some embodiments, the first nitride layer has a density less than a density of the second nitride layer. In some embodiments, the first nitride layer is doped with a dopant, and the second nitride layer is free of the dopant. In some embodiments, the first nitride layer has a thickness less than the thickness of the second nitride layer. In some embodiments, the method further includes forming an air gap around the source/drain contact.

In some embodiments, a device includes a channel region (e.g., nanostructure 204 or fin structure 402); a gate structure (e.g., gate structure 240 or 420) over the channel region; an epitaxial structure (e.g., epitaxial source/drain region 232 or 410) interfacing a sidewall of the channel region, wherein the epitaxial structure is doped with a dopant, wherein the epitaxial structure comprises a first layer (e.g., first semiconductor material layer 232A or 412) adjacent the sidewall of the channel region, and a second layer (e.g., second semiconductor material layer 234B or 414) away from the sidewall of the channel region, wherein a concentration of the dopant in the first layer is different from a concentration of the dopant in the second layer; a first ILD layer (e.g., ILD layer 236 or 434) over the epitaxial structure; a source/drain contact (e.g., contact 270 or 450) extending through the first ILD layer to electrically couple to the epitaxial structure, wherein an electrical conductivity of the source/drain contact is greater than an electrical conductivity of the epitaxial structure; a multi-layered etch stop layer (e.g., MCESL 280 or 460) over the source/drain contact, the multi-layered etch stop layer comprising a first nitride layer (e.g., sub-layer 282 or 462), a second nitride layer (e.g., sub-layer 284 or 464), and an oxide layer (e.g., oxide layer 283 or 463) between the first nitride layer and the second nitride layer, wherein the oxide layer has a thickness less than a thickness of the first nitride layer; a second ILD layer (e.g., ILD layer 290 or 470) over the multi-layered etch stop layer; and a source/drain via (e.g., source/drain via 302 or 480) extending through the second ILD layer and the multi-layered etch stop layer to the source/drain contact. In some embodiments, the thickness of the oxide layer is less than a thickness of the second nitride layer. In some embodiments, the thickness of the first nitride layer is less than a thickness of the second nitride layer. In some embodiments, the second nitride layer has a density greater than a density of the first nitride layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a source/drain feature over a substrate;
forming a first interlayer dielectric (ILD) layer over the source/drain feature;
forming a metal silicide layer over the source/drain feature;
forming a source/drain contact in the first ILD layer to electrically couple to the source/drain feature through the metal silicide layer, wherein an electrical conductivity of the metal silicide layer is between an electrical conductivity of the source/drain feature and an electrical conductivity of the source/drain contact;
forming a first sub-layer of an etch stop layer over the first ILD layer and the source/drain contact;
performing an ion implantation process on the first sub-layer of the etch stop layer;
after performing the ion implantation process, forming a second sub-layer of the etch stop layer over the first sub-layer of the etch stop layer;
forming a second ILD layer over the second sub-layer of the etch stop layer; and
forming a source/drain via extending through the second ILD layer, the second sub-layer of the etch stop layer, and the first sub-layer of the etch stop layer to the source/drain contact.

2. The method of claim 1, further comprising:
forming an air gap in the first ILD layer.

3. The method of claim 2, wherein after the ion implantation process, the air gap has a top end lower than a top surface of the first ILD layer.

4. The method of claim 1, wherein after the ion implantation process, the first sub-layer of the etch stop layer comprises an implantation species derived from the ion implantation process.

5. The method of claim 4, wherein the second sub-layer of the etch stop layer is free of the implantation species derived from the ion implantation process.

6. The method of claim 1, wherein the second sub-layer of the etch stop layer is in contact with an oxide formed on the first sub-layer of the etch stop layer.

7. The method of claim 6, wherein the oxide is thinner than the second sub-layer of the etch stop layer.

8. The method of claim 6, wherein the oxide is thinner than the first sub-layer of the etch stop layer.

9. The method of claim 6, wherein the source/drain via forms a non-linear interface with the second sub-layer of the etch stop layer, the oxide, and the first sub-layer of the etch stop layer.

10. The method of claim 1, wherein the first sub-layer of the etch stop layer is thinner than the second sub-layer of the etch stop layer.

11. A method comprising:
forming a channel region over a substrate;
forming a silicon-containing structure having a first semiconductor layer adjacent to the channel region and a second semiconductor layer spaced apart from the channel region by the first semiconductor layer, wherein a composition of the first semiconductor layer is different from a composition of the second semiconductor layer, wherein a thickness of the silicon-containing structure is different from a width of the silicon-containing structure in a cross-sectional view;
forming a first ILD layer over the silicon-containing structure;
forming a source/drain contact extending through the first ILD layer to electrically couple to the silicon-containing structure;
forming a multi-layered etch stop layer over the source/drain contact, the multi-layered etch stop layer comprising a first nitride layer, a second nitride layer, and an oxide layer interposing the first nitride layer and the second nitride layer, wherein the oxide layer has a thickness less than a thickness of the second nitride layer;
forming a second ILD layer over the multi-layered etch stop layer; and
forming a via structure extending through the second ILD layer and the multi-layered etch stop layer to the source/drain contact.

12. The method of claim 11, wherein the thickness of the oxide layer is less than a thickness of the first nitride layer.

13. The method of claim 11, wherein the first nitride layer has a density less than a density of the second nitride layer.

14. The method of claim 11, wherein the first nitride layer is doped with a dopant, and the second nitride layer is free of the dopant.

15. The method of claim 11, wherein the first nitride layer has a thickness less than the thickness of the second nitride layer.

16. The method of claim 11, further comprising:
forming an air gap around the source/drain contact.

17. A device comprising:
a channel region;
a gate structure over the channel region;
an epitaxial structure interfacing a sidewall of the channel region, wherein the epitaxial structure is doped with a dopant, wherein the epitaxial structure comprises a first layer adjacent the sidewall of the channel region, and a second layer away from the sidewall of the channel region, wherein a concentration of the dopant in the first layer is different from a concentration of the dopant in the second layer;
a first ILD layer over the epitaxial structure;
a source/drain contact extending through the first ILD layer to electrically couple to the epitaxial structure, wherein an electrical conductivity of the source/drain contact is greater than an electrical conductivity of the epitaxial structure;
a multi-layered etch stop layer over the source/drain contact, the multi-layered etch stop layer comprising a first nitride layer, a second nitride layer, and an oxide layer between the first nitride layer and the second nitride layer, wherein the oxide layer has a thickness less than a thickness of the first nitride layer;
a second ILD layer over the multi-layered etch stop layer; and
a source/drain via extending through the second ILD layer and the multi-layered etch stop layer to the source/drain contact.

18. The device of claim 17, wherein the thickness of the oxide layer is less than a thickness of the second nitride layer.

19. The device of claim 17, wherein the thickness of the first nitride layer is less than a thickness of the second nitride layer.

20. The device of claim 17, wherein the second nitride layer has a density greater than a density of the first nitride layer.
